(19) United States
(12) Patent Application Publication
(10) Pub. No.: US 2024/0282710 A1
(43) Pub. Date: Aug. 22, 2024

(54) SEMICONDUCTOR DEVICE CONTAINING DIVOT-FILL DIELECTRIC BARRIER FOR METAL-TO-METAL CONTACTS AND METHODS FOR MANUFACTURING THE SAME

(71) Applicant: SANDISK TECHNOLOGIES LLC, ADDISON, TX (US)

(72) Inventors: Linghan CHEN, Nagoya (JP); Fumitaka AMANO, Yokkaichi (JP)

(21) Appl. No.: 18/359,610

(22) Filed: Jul. 26, 2023

Related U.S. Application Data
(60) Provisional application No. 63/486,314, filed on Feb. 22, 2023.

(51) Int. Cl. H01L 23/532; H01L 21/768; H01L 23/522

(52) U.S. Cl. CPC H01L 23/5329; H01L 21/76834; H01L 21/76843; H01L 21/76877; H01L 23/5226; H01L 23/53238; H10B 43/20; H10B 51/20; H10B 63/10

(57) ABSTRACT

A device structure includes a first dielectric material layer, a first conductive interconnect structure embedded in the first dielectric material layer and including a first metallic barrier liner and a first metal fill material portion having a top surface within a first horizontal plane, where the first metallic barrier liner laterally surrounds the first metal fill material portion and has a top surface below the first horizontal plane such that a moat-shaped divot is located between the first metal fill material portion and the first dielectric material layer, a divot-fill dielectric portion located in the moat-shaped divot and contacting the top surface of the first metallic barrier liner, a second dielectric material layer overlying the first dielectric material layer, and a second conductive interconnect structure embedded in the second dielectric material layer and contacting at least a segment of the top surface of the first metal fill material portion.

### FIELD

The present disclosure relates generally to the field of semiconductor devices, and particularly to a semiconductor device including divot-fill dielectric barrier for metal-to-metal contacts and methods for manufacturing the same.

### BACKGROUND

Three-dimensional vertical NAND strings having one bit per cell are disclosed in an article by T. Endoh et al., titled “Novel Ultra High Density Memory With A Stacked-Surrounding Gate Transistor (S-SGT) Structured Cell”, IEDM Proc. (2001) 33-36.

### SUMMARY

According to an aspect of the present disclosure, a device structure includes a first dielectric material layer, a first conductive interconnect structure embedded in the first dielectric material layer and including a first metallic barrier liner and a first metal fill material portion having a top surface within a first horizontal plane, where the first metallic barrier liner laterally surrounds the first metal fill material portion and has a top surface below the first horizontal plane such that a moat-shaped divot is located between the first metal fill material portion and the first dielectric material layer, a divot-fill dielectric portion located in the moat-shaped divot and contacting the top surface of the first metallic barrier liner, a second dielectric material layer overlying the first dielectric material layer, and a second conductive interconnect structure embedded in the second dielectric material layer and contacting at least a segment of the top surface of the first metal fill material portion.

According to another aspect of the present disclosure, a method of forming a device structure is provided. The method comprises: forming a first dielectric material layer over a substrate; forming a first conductive interconnect structure in the first dielectric material layer, wherein the first conductive interconnect structure comprises a first metallic barrier liner and a first metal fill material portion having a top surface within a first horizontal plane including a top surface of the first dielectric material layer and laterally surrounded by the first metallic barrier liner; selectively recessing a top surface of the first metallic barrier liner relative to the first metal fill material portion and the first dielectric material layer, wherein a moat-shaped divot is formed between the first metal fill material portion and the first dielectric material layer; forming a dielectric diffusion barrier layer over the first conductive interconnect structure and the first dielectric material layer, wherein the dielectric diffusion barrier layer comprises a downward-protruding divot-fill dielectric portion filling the moat-shaped divot; forming a second dielectric material layer over the dielectric diffusion barrier layer; and forming a second conductive interconnect structure through the dielectric diffusion barrier layer and the second dielectric material layer and directly on a segment of the top surface of the first metal fill material portion.

### BRIEF DESCRIPTION OF THE DRAWINGS

FIG. 1 is a schematic vertical cross-sectional view of an exemplary structure after formation of an alternating stack of insulating layers and sacrificial material layers and first dielectric material portions over a carrier substrate according to an embodiment of the present disclosure.

FIG. 2 is a schematic vertical cross-sectional view of the exemplary structure after patterning the alternating stack and formation of dielectric material portions according to an embodiment of the present disclosure.

FIG. 3A is a schematic vertical cross-sectional view of the exemplary structure after formation of memory openings according to an embodiment of the present disclosure.

FIG. 3B is a top-down view of the exemplary structure of FIG. 3A. The vertical plane A-A′ is the cut plane of the vertical cross-sectional view of FIG. 3A.

FIGS. 4A-4D are sequential vertical cross-sectional views of a memory opening during formation of a memory opening fill structure according to an embodiments of the present disclosure.

FIG. 5A is a vertical cross-sectional view of the exemplary structure after formation of memory opening fill structures according to an embodiment of the present disclosure.

FIG. 5B is a top-down view of the exemplary structure of FIG. 5A. The vertical plane A-A′ is the cut plane of the vertical cross-sectional view of FIG. 5A.

FIG. 6A is a vertical cross-sectional view of the exemplary structure after formation of lateral isolation trenches according to an embodiment of the present disclosure.

FIG. 6B is a top-down view of the exemplary structure of FIG. 6A. The vertical plane A-A′ is the cut plane of the vertical cross-sectional view of FIG. 6A.

FIG. 7 is a vertical cross-sectional view of the exemplary structure after formation of lateral recesses according to an embodiment of the present disclosure.

FIG. 8 is a vertical cross-sectional view of the exemplary structure after formation of electrically conductive layers according to an embodiment of the present disclosure.

FIG. 9 is a vertical cross-sectional view of the exemplary structure after formation of lateral isolation trench fill structures according to an embodiment of the present disclosure.

FIG. 10A is a vertical cross-sectional view of the exemplary structure after formation of contact via structures according to an embodiment of the present disclosure.

FIG. 10B is a top-down view of the exemplary structure of FIG. 10A. The vertical plane A-A′ is the cut plane of the vertical cross-sectional view of FIG. 10A.

FIG. 11A is a vertical cross-sectional view of the exemplary structure after formation of connection via structures and first-line-level metal lines including bit lines according to an embodiment of the present disclosure.

FIG. 11B is a top-down view of the exemplary structure of FIG. 11A. The vertical plane A-A′ is the cut plane of the vertical cross-sectional view of FIG. 11A.

FIG. 11C is a magnified vertical cross-sectional view of a region of the exemplary structure along the vertical plane C-C′ of FIG. 11B.

FIGS. 12A-12E are sequential vertical cross-sectional views of a region of the exemplary structure during formation of metal via structures and second-line-level metal lines according to an embodiment of the present disclosure.

FIG. 12F is a plan view of the region of the exemplary structure illustrated in FIG. 12E.

FIG. 12G is a vertical cross-sectional view of a region of an alternative configuration of the exemplary structure after formation of metal via structures and second-line-level metal lines according to an embodiment of the present disclosure.

FIG. 13 is a vertical cross-sectional view of the exemplary structure after formation of a memory die and attachment of a logic die to the memory die according to an embodiment of the present disclosure.

FIG. 14 is a vertical cross-sectional view of the exemplary structure after removal of the carrier substrate according to an embodiment of the present disclosure.

FIG. 15 is a vertical cross-sectional view of the exemplary structure after patterning source layers, at least one backside dielectric layer, and backside bonding pads according to an embodiment of the present disclosure.

### DETAILED DESCRIPTION

As discussed above, the present disclosure is directed to a semiconductor device including a divot-fill dielectric barrier for metal-to-metal contacts and methods for manufacturing the same, the various aspects of which are described below.

The present inventors realized that if a fluorine containing precursor (e.g., tungsten hexafluoride) is used to form a conductive (e.g., tungsten) interconnect (e.g., via contact) to a copper line (e.g., bit line of a memory device), then the residual fluorine from the interconnect may diffuse into and attack the conductive barrier layer (e.g., titanium or tantalum) located on the sides of the copper line. The fluorine attack causes damage to the conductive barrier layer, which may cause the conductive barrier layer to become a less effective or ineffective diffusion barrier, which results in degradation of the semiconductor device. The divot-fill dielectric barrier of the embodiments of the present disclosure separates the conductive barrier layer from the fluorine containing interconnect material. Thus, the divot-fill dielectric barrier reduces fluorine diffusion and damage to the conductive barrier layer. Embodiments of the disclosure can be employed to form various structures including a multilevel memory structure, non-limiting examples of which include semiconductor devices, such as three-dimensional memory array devices comprising a plurality of memory strings.

The drawings are not drawn to scale. Multiple instances of an element may be duplicated where a single instance of the element is illustrated, unless absence of duplication of elements is expressly described or clearly indicated otherwise. Ordinals such as “first,” “second,” and “third” are employed merely to identify similar elements, and different ordinals may be employed across the specification and the claims of the instant disclosure. The term “at least one” element refers to all possibilities including the possibility of a single element and the possibility of multiple elements.

The same reference numerals refer to the same element or similar element. Unless otherwise indicated, elements having the same reference numerals are presumed to have the same composition and the same function. Unless otherwise indicated, a “contact” between elements refers to a direct contact between elements that provides an edge or a surface shared by the elements. If two or more elements are not in direct contact with each other or among one another, the two elements are “disjoined from” each other or “disjoined among” one another. As used herein, an element located “on” a second element can be located on the exterior side of a surface of the second element or on the interior side of the second element. As used herein, an element is located “directly on” a second element if there exist a physical contact between a surface of the element and a surface of the second element. As used herein, an element is “electrically connected to” a second element if there exists a conductive path consisting of at least one conductive material between the element and the second element. As used herein, a “prototype” structure or an “in-process” structure refers to a transient structure that is subsequently modified in the shape or composition of at least one component therein.

As used herein, a “layer” refers to a material portion including a region having a thickness. A layer may extend over the entirety of an underlying or overlying structure, or may have an extent less than the extent of an underlying or overlying structure. Further, a layer may be a region of a homogeneous or inhomogeneous continuous structure that has a thickness less than the thickness of the continuous structure. For example, a layer may be located between any pair of horizontal planes between, or at, a top surface and a bottom surface of the continuous structure. A layer may extend horizontally, vertically, and/or along a tapered surface. A substrate may be a layer, may include one or more layers therein, or may have one or more layer thereupon, thereabove, and/or therebelow.

Generally, a semiconductor die, or a semiconductor package, can include a memory chip. Each semiconductor package contains one or more dies (for example one, two, or four). The die is the smallest unit that can independently execute commands or report status. Each die contains one or more planes (typically one or two). Identical, concurrent operations can take place on each plane, although with some restrictions. Each plane contains a number of blocks, which are the smallest unit that can be erased in a single erase operation. Each block contains a number of pages, which are the smallest unit that can be programmed, i.e., a smallest unit on which a read operation can be performed.

As used herein, a “semiconducting material” refers to a material having electrical conductivity in the range from 1.0×10⁻⁵ S/m to 1.0×10⁵ S/m. As used herein, a “semiconductor material” refers to a material having electrical conductivity in the range from 1.0×10⁻⁵ S/m to 1.0 S/m in the absence of electrical dopants therein, and is capable of producing a doped material having electrical conductivity in a range from 1.0 S/m to 1.0×10⁷ S/m upon suitable doping with an electrical dopant. As used herein, an “electrical dopant” refers to a p-type dopant that adds a hole to a valence band within a band structure, or an n-type dopant that adds an electron to a conduction band within a band structure. As used herein, a “conductive material” refers to a material having electrical conductivity greater than 1.0×10⁵ S/m. As used herein, an “insulator material” or a “dielectric material” refers to a material having electrical conductivity less than 1.0×10⁻⁵ S/m. As used herein, a “heavily doped semiconductor material” refers to a semiconductor material that is doped with electrical dopant at a sufficiently high atomic concentration to become a conductive material either as formed as a crystalline material or if converted into a crystalline material through an anneal process (for example, from an initial amorphous state), i.e., to provide electrical conductivity greater than 1.0×10⁵ S/m. A “doped semiconductor material” may be a heavily doped semiconductor material, or may be a semiconductor material that includes electrical dopants (i.e., p-type dopants and/or n-type dopants) at a concentration that provides electrical conductivity in the range from 1.0×10⁻⁵ S/m to 1.0×10⁷ S/m. An “intrinsic semiconductor material” refers to a semiconductor material that is not doped with electrical dopants. Thus, a semiconductor material may be semiconducting or conductive, and may be an intrinsic semiconductor material or a doped semiconductor material. A doped semiconductor material may be semiconducting or conductive depending on the atomic concentration of electrical dopants therein. As used herein, a “metallic material” refers to a conductive material including at least one metallic element therein. All measurements for electrical conductivities are made at the standard condition.

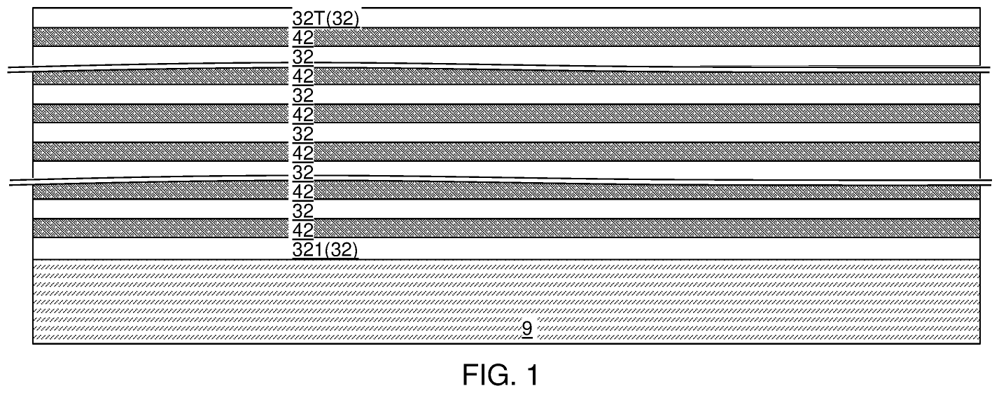

Referring to FIG. 1, an exemplary structure according to an embodiment of the present disclosure is illustrated. The exemplary structure comprises a carrier substrate 9, which may be a semiconductor substrate or a conductive substrate. For example, the carrier substrate 9 may comprise a commercially available silicon wafer. Alternatively, the carrier substrate 9 may comprise any material that may be removed selective the materials of insulating layers 32 and dielectric material portions to be subsequently formed.

An alternating stack of insulating layers 32 and spacer material layers can be formed over the carrier substrate 9. In one embodiment, the spacer material layers may comprise sacrificial material layers 42. In this case, an alternating stack (32, 42) of insulating layers 32 and sacrificial material layers 42 can be formed over the carrier substrate 9. The insulating layers 32 comprise an insulating material such as undoped silicate glass or a doped silicate glass, and the sacrificial material layers 42 comprise a sacrificial material such as silicon nitride or a silicon-germanium alloy. The alternating stack (32, 42) may comprise multiple repetitions of a unit layer stack including an insulating layer 32 and a sacrificial material layer 42. The total number of repetitions of the unit layer stack within the alternating stack (32, 42) may be, for example, in a range from 8 to 1,024, such as from 32 to 256, although lesser and greater number of repetitions may also be employed. The topmost one of the insulating layers 32 is hereafter referred to as a topmost insulating layer 32T. The bottommost one of the insulating layers 32 is an insulating layer 32 that is most proximal to the carrier substrate 9 or to backside structures to be subsequently formed in lieu of the carrier substrate 9, and may be referred to as a most proximal insulating layer 321.

Each of the insulating layers 32 other than the topmost insulating layer 32 may have a thickness in a range from 20 nm to 100 nm, such as from 30 nm to 60 nm, although lesser and greater thicknesses may also be employed. Each of the sacrificial material layers 42 may have a thickness in a range from 20 nm to 100 nm, such as from 30 nm to 60 nm, although lesser and greater thicknesses may also be employed. In one embodiment, the topmost insulating layer 32 may have a thickness of about one half of the thickness of other insulating layers 32.

While an embodiment is described in which the spacer material layers are formed as sacrificial material layers 42, the spacer material layers may be formed as first electrically conductive layers in an alternative embodiment. Generally, spacer material layers may be formed as or may be subsequently replaced at least partly with electrically conductive layers.

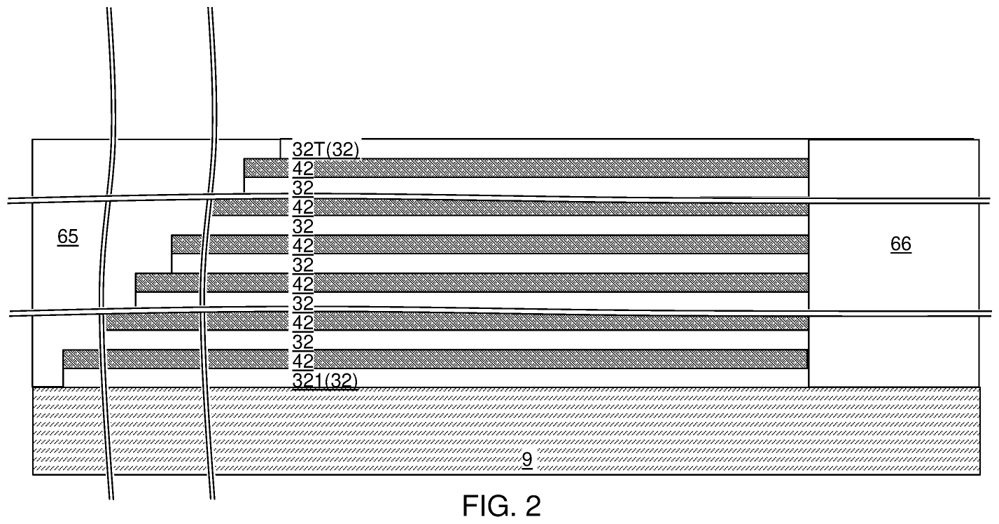

Referring to FIG. 2, stepped surfaces may be formed by patterning one side of the alternating stack (32, 42). Another side of the alternating stack (32, 42) may be optionally removed to provide a straight sidewall that extends from a bottommost surface to a topmost surface of the alternating stack (32, 42). A dielectric fill material such as undoped silicate glass or a doped silicate glass can be deposited over the alternating stack (32, 42), and excess portions of the dielectric fill material may be removed from above the horizontal plane including the top surface of the topmost insulating layer 32 by a planarization process, which may employ a chemical mechanical polishing process and/or a recess etch process. A retro-stepped dielectric material portion 65 may be formed over the stepped surfaces. An optional field dielectric material portion 66 may be formed over a top surface of the carrier substrate 9 adjacent to a straight sidewall of the alternating stack (32, 42). The retro-stepped dielectric material portion 65 and the field dielectric material portion 66 are herein collectively referred to as dielectric material portions (65, 66).

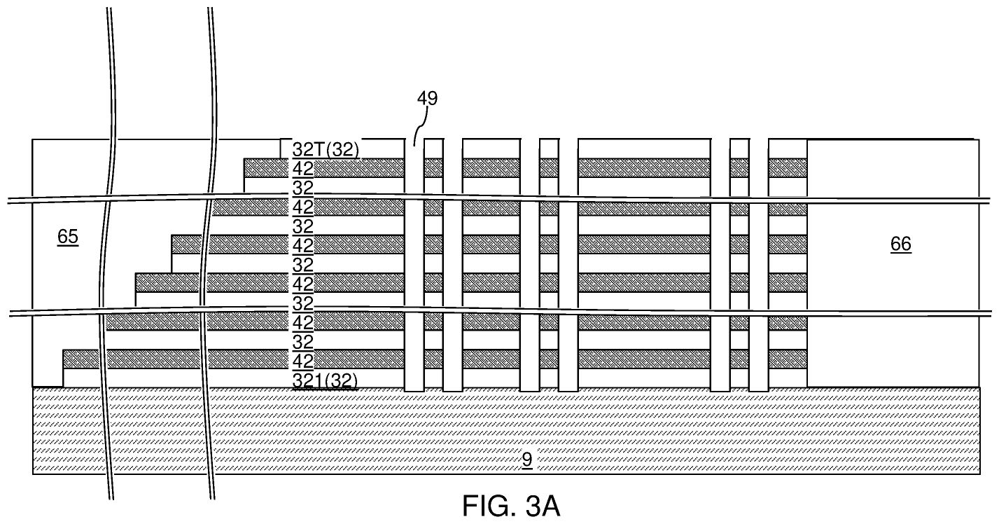

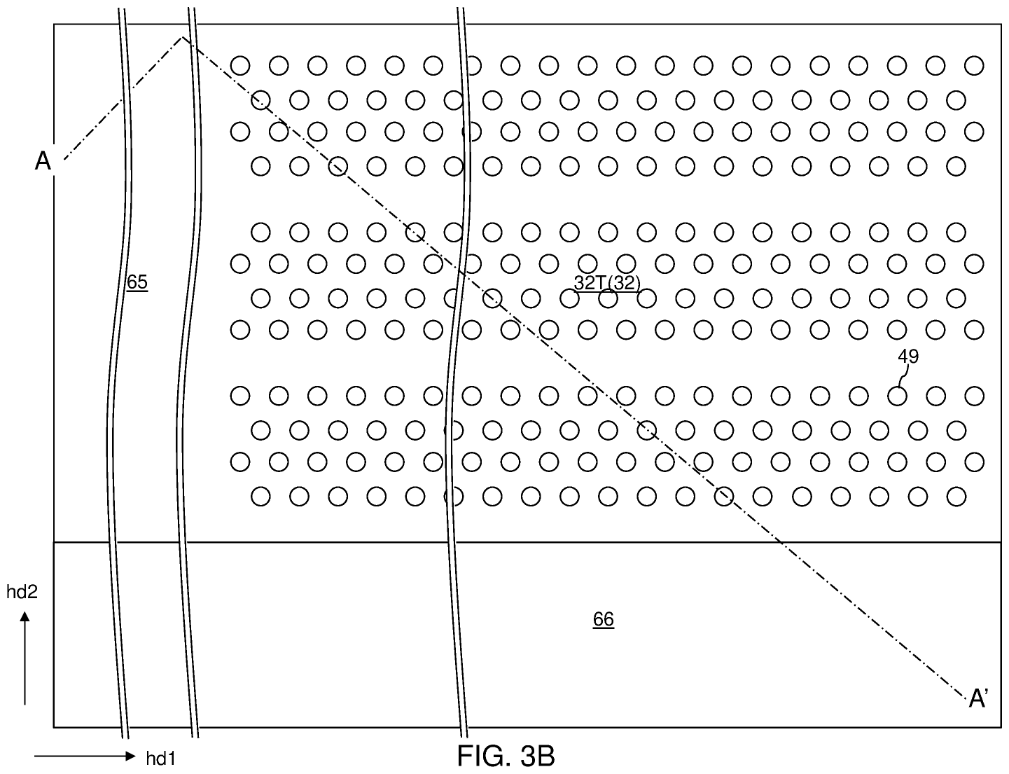

Referring to FIGS. 3A and 3B, an etch mask layer (not shown) can be formed over the alternating stack (32, 42), and can be lithographically patterned to form various openings therein. An anisotropic etch process can be performed to transfer the pattern of the openings in the etch mask layer through the alternating stack (32, 42). Various openings can be formed through the alternating stack (32, 42). The various openings may comprise memory openings 49 that vertically extend through each layer within the alternating stack (32, 42), and additional openings such as support openings (not illustrated) that are formed in the areas of the retro-stepped dielectric material portion 65 and subsequently employed to form support pillar structures. In one embodiment, the memory openings 49 may be formed in rows that laterally extend along a first horizontal direction hd1. The rows of memory openings 49 may be arranged along a second horizontal direction hd2 that is perpendicular to the first horizontal direction hd1. The etch mask layer can be subsequently removed.

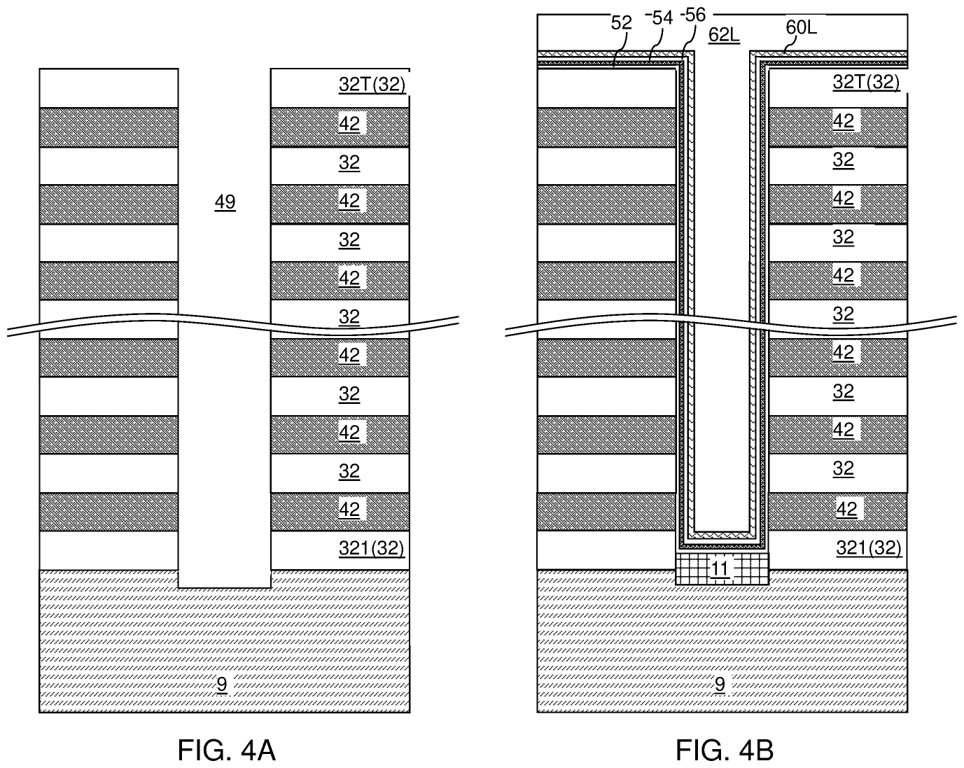

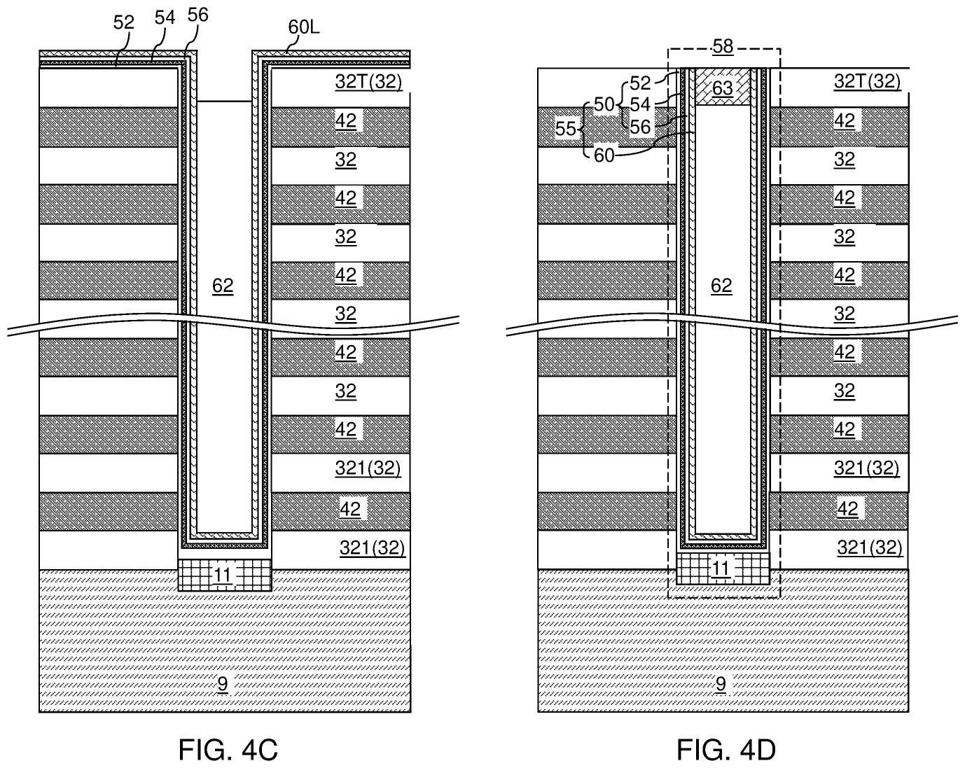

FIGS. 4A-4D are sequential vertical cross-sectional views of a memory opening 49 during formation of a memory opening fill structure 58 according to embodiments of the present disclosure.

Referring to FIG. 4A, a memory opening 49 is illustrated after the processing steps of FIGS. 3A and 3B.

Referring to FIG. 4B, sacrificial pillar structures 11 can be formed at the bottom of the memory openings 49. The sacrificial pillar structures 11 may comprise a sacrificial material that can be subsequently removed. For example, the sacrificial pillar structures 11 can comprise a semiconductor material (e.g., single crystalline silicon), a carbon-based material (such as amorphous carbon or diamond-like carbon (DLC), or a high-etch-rate dielectric material such as borosilicate glass. In case the sacrificial pillar structures 11 comprise a semiconductor material, the sacrificial pillar structures 11 can be formed by selective growth of the semiconductor material from physically exposed surfaces of the carrier substrate 9. A selective semiconductor deposition process such as a selective epitaxy process may be employed to form the sacrificial pillar structures 11.

Subsequently, a layer stack including a memory material layer 54 can be conformally deposited. In an illustrative example, the layer stack may comprise an optional blocking dielectric layer 52, the memory material layer 54, and an optional dielectric liner 56. The memory material layer 54 includes a memory material, i.e., a material that can store data bits therein. The memory material layer 54 may comprise a charge storage material (such as silicon nitride), a ferroelectric material, a phase change memory material, or any other memory material that can store data bits by inducing a change in the electrical resistivity, ferroelectric polarization, or any other measurable physical property. In case the memory material layer 54 comprise a charge storage material, the optional dielectric liner 56 may comprise a tunneling dielectric layer.

A semiconductor channel material layer 60L can be deposited over the layer stack (52, 54, 56) by performing a conformal deposition process. If the semiconductor channel material layer 60L is doped, the semiconductor channel material layer 60L may have a doping of a first conductivity type, which may be p-type or n-type. In one embodiment, the first semiconductor material comprises a first doped silicon material having a doping of the first conductivity type. In an illustrative example, the atomic concentration of dopants of the first conductivity type in the semiconductor channel material layer 60L may be in a range from 1.0×10¹³/cm³ to 3.0×10¹⁷/cm³, such as 1.0×10¹⁴/cm³ to 3.0×10¹⁶/cm³, although lesser and greater atomic concentrations may also be employed. A dielectric core layer 62L comprising a dielectric fill material can be deposited in remaining volumes of the memory openings 49 and over the alternating stack (32, 42).

Referring to FIG. 4C, the dielectric core layer 62L can be vertically recessed such that each remaining portion of the dielectric core layer 62L has a top surface at, or about, the horizontal plane including the bottom surface of the topmost insulating layers 32T. Each remaining portion of the dielectric core layer 62L constitutes a dielectric core 62.

Referring to FIG. 4D, a doped semiconductor material having a doping of a second conductivity type can be deposited within each recessed region above the dielectric cores 62. The second conductivity type is the opposite of the first conductivity type. For example, if the first conductivity type is p-type, the second conductivity type is n-type, and vice versa. The dopant concentration in the deposited semiconductor material can be in a range from 5.0×10¹⁸/cm³ to 2.0×10²¹/cm³, although lesser and greater dopant concentrations can also be employed. The doped semiconductor material can be, for example, doped polysilicon.

Excess portions of the deposited semiconductor material having a doping of the second conductivity type and a horizontal portion of the semiconductor channel layer 60L can be removed from above the horizontal plane including the top surface of the topmost insulating layer 32T, for example, by chemical mechanical planarization (CMP) or a recess etch process. Each remaining portion of the doped semiconductor material having a doping of the second conductivity type constitutes a drain region 63. Each remaining portion of the semiconductor channel layer 60L (which has a doping of the first conductivity type) constitutes a vertical semiconductor channel 60.

Each portion of the layer stack including the memory material layer 54 that remains in a respective memory opening 49 constitutes a memory film 50. In one embodiment, a memory film 50 may comprise an optional blocking dielectric layer 52, a memory material layer 54, and an optional dielectric liner 56. Each contiguous combination of a memory film 50 and a vertical semiconductor channel 60 constitutes a memory stack structure 55. Each combination of a sacrificial pillar structure 11, a memory stack structure 55, a dielectric core 62, and a drain region 63 within a memory opening 49 constitutes a memory opening fill structure 58. Each memory opening fill structure 58 comprises a respective vertical stack of memory elements, which may be embodied as portions of the memory material layer 54 located at levels of the sacrificial material layers 42, or generally speaking, at levels of spacer material layers that may be formed as, or may be subsequently replaced at least partly with, electrically conductive layers.

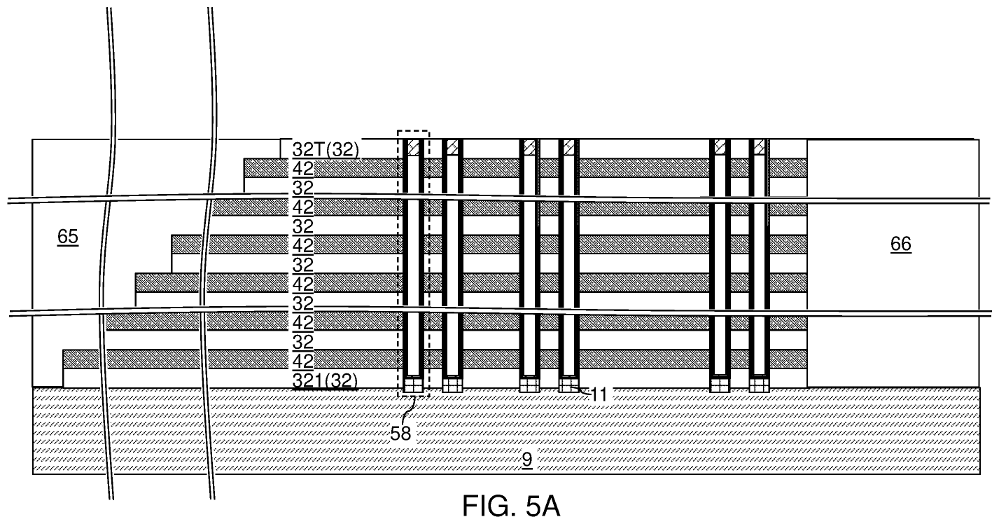

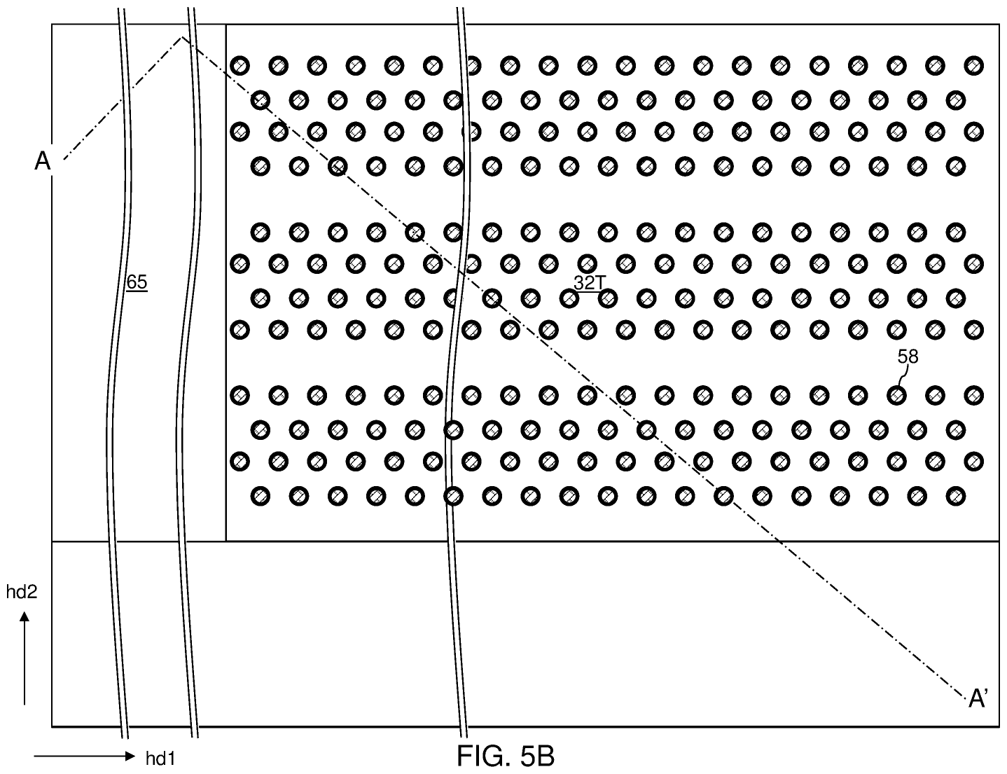

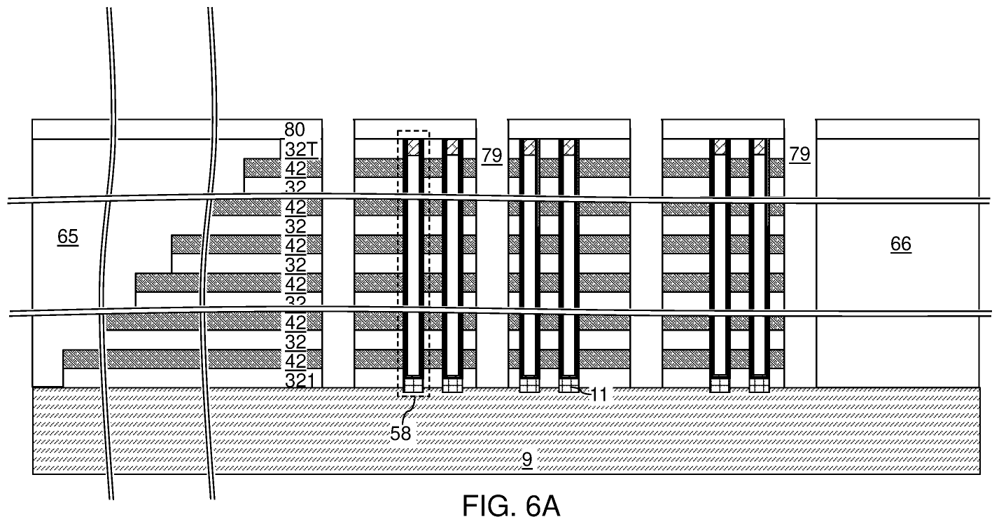

Referring to FIGS. 5A and 5B, the exemplary structure is illustrated after formation of memory opening fill structures 58 within the memory openings 49. Each of the memory opening fill structures 58 may comprise a sacrificial pillar structure 11 on which a memory film 50 and a vertical semiconductor channel 60 are formed. Optionally, support pillar structures (not shown) may be formed in support openings (not shown) through the alternating stack (32, 42) concurrently with formation of the memory opening fill structures 58 such that each of the support pillar structures has a substantially same structure as a memory opening fill structure 58. Alternatively or additionally, dielectric support pillar structures may be formed in support openings through the alternating stack (32, 42) prior to, or after, formation of the memory opening fill structures 58.

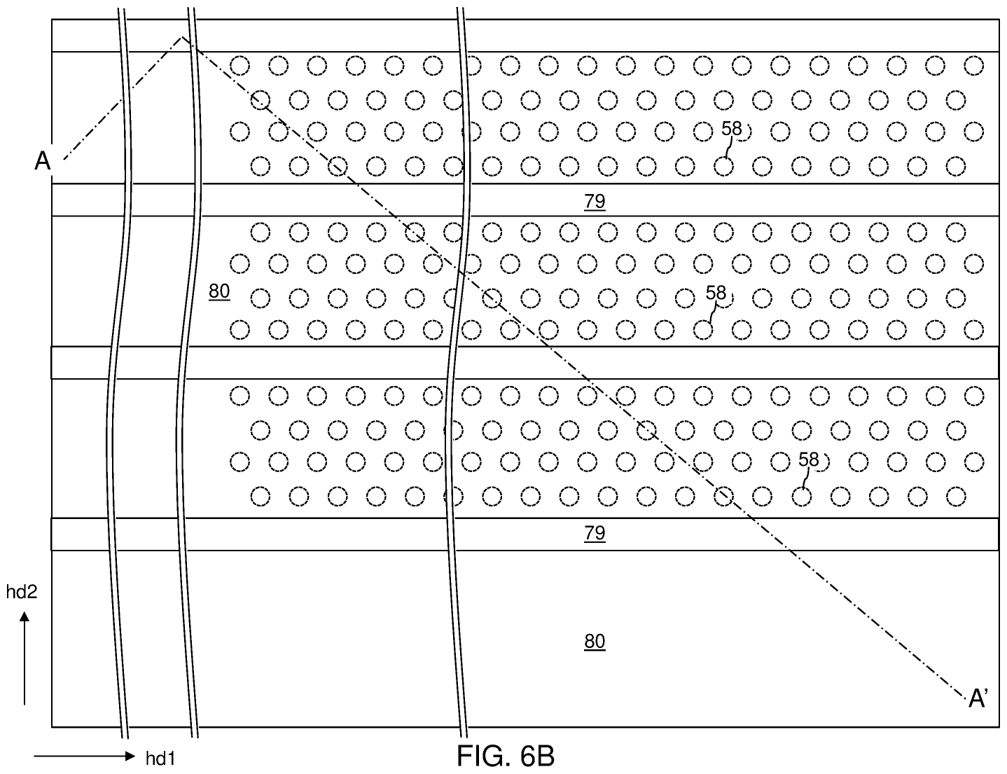

Referring to FIGS. 6A and 6B, a contact-level dielectric layer 80 can be formed over the alternating stack (32, 42). A photoresist layer (not shown) can be applied over the contact-level dielectric layer 80, and can be lithographically patterned to form elongated openings that laterally extend along the first horizontal direction (e.g., word line direction) hd1 between neighboring clusters of memory opening fill structures 58. An anisotropic etch process can be performed to transfer the pattern of the openings in the photoresist layer through the contact-level dielectric layer 80, the alternating stack (32, 42), and the dielectric material portions (65, 66). Lateral isolation trenches 79 laterally extending along the first horizontal direction hd1 can be formed through the alternating stack (32, 42), the dielectric material portions (65, 66), and the contact-level dielectric layer 80. Each of the lateral isolation trenches 79 may comprise a respective pair of lengthwise sidewalls that are parallel to the first horizontal direction hd1 and vertically extend from the carrier substrate 9 to the top surface of the contact-level dielectric layer 80. A top surface of the carrier substrate 9 can be physically exposed underneath each lateral isolation trench 79. The photoresist layer can be subsequently removed, for example, by ashing.

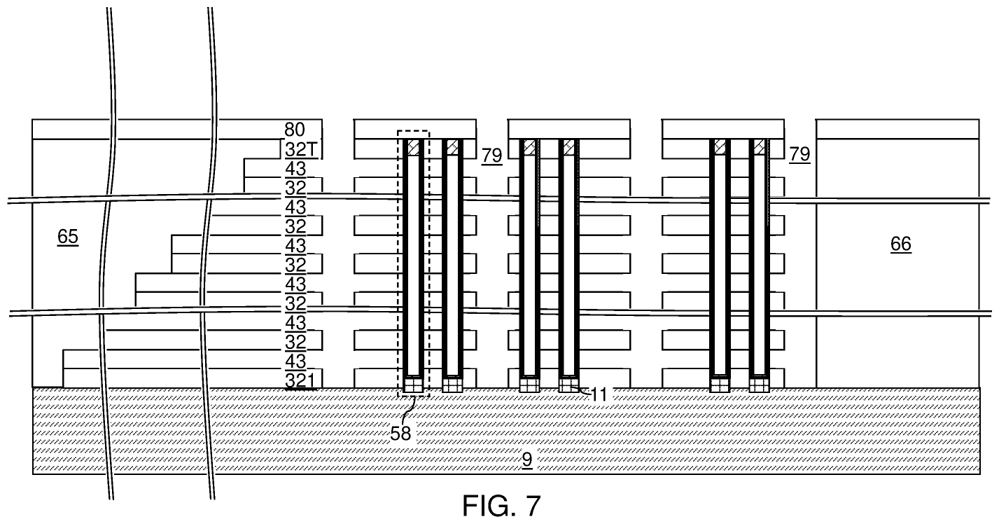

Referring to FIG. 7, an isotropic etch process can be performed to remove the sacrificial material layers 42 selective to the insulating layers 32, the memory opening fill structures 58, and the carrier substrate 9. Lateral recesses 43 can be formed in volumes from which the sacrificial material layers 42 are removed. Sidewall surface segments of the memory opening fill structures 58 can be physically exposed to the lateral recesses 43. In an illustrative example, if the sacrificial material layers 42 comprise silicon nitride, the isotropic etch process may comprise a wet etch process employing hot phosphoric acid.

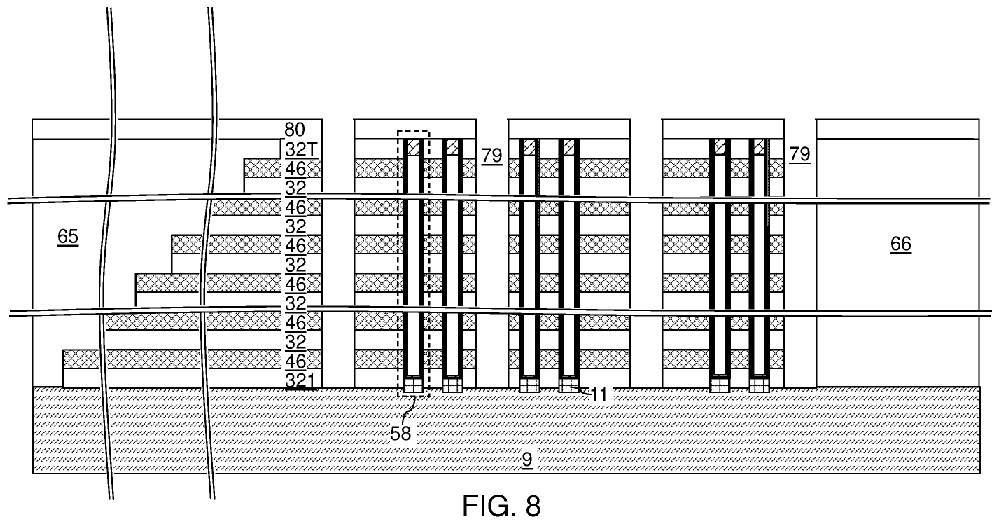

Referring to FIG. 8, a backside blocking dielectric layer (not shown) can be optionally formed in the lateral recesses 43 by a conformal deposition process. At least one conductive material, such as at least one metallic material, can be conformally deposited in the lateral recesses 43. The at least one conductive material may comprise, for example, a combination of a metallic barrier material and a metal fill material. The metallic barrier material may comprise, for example, TiN, TaN, WN, MoN, TiC, TaC, WC, or a combination thereof. The metal fill material may comprise, for example, Ti, Ta, Mo, Co, Ru, W, Cu, other transition metals, and/or alloys or layer stacks thereof. Excess portions of the at least one conductive material that are deposited in the lateral isolation trenches 79 or above the contact-level dielectric layer 80 can be removed by performing an etch-back process, which may comprise an isotropic etch process and/or an anisotropic etch process. Each remaining portion of the at least one conductive material filling a respective one of the lateral recesses 43 constitutes an electrically conductive layer 46. An alternating stack of insulating layers 32 and electrically conductive layers 46 can be formed between each neighboring pair of lateral isolation trenches 79 over the carrier substrate 8. A plurality of alternating stacks of insulating layers 32 and electrically conductive layers 46 can be laterally spaced apart from each other by the lateral isolation trenches 79.

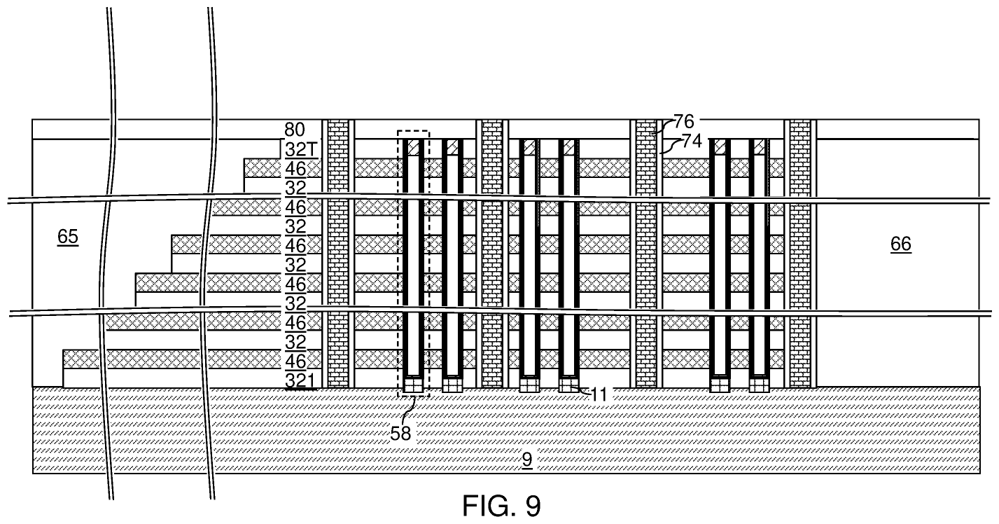

Referring to FIG. 9, an insulating material may be conformally deposited and anisotropically etched to form an insulating spacer at the periphery of each of the lateral isolation trenches 79. At least one conductive fill material may be deposited in remaining volumes of the lateral isolation trenches 79 to form a local interconnect 76. Each contiguous combination of a local interconnect 76 and an insulating spacer 74 constitutes an isolation trench fill structure (74, 76) that fills a respective lateral isolation trench 79.

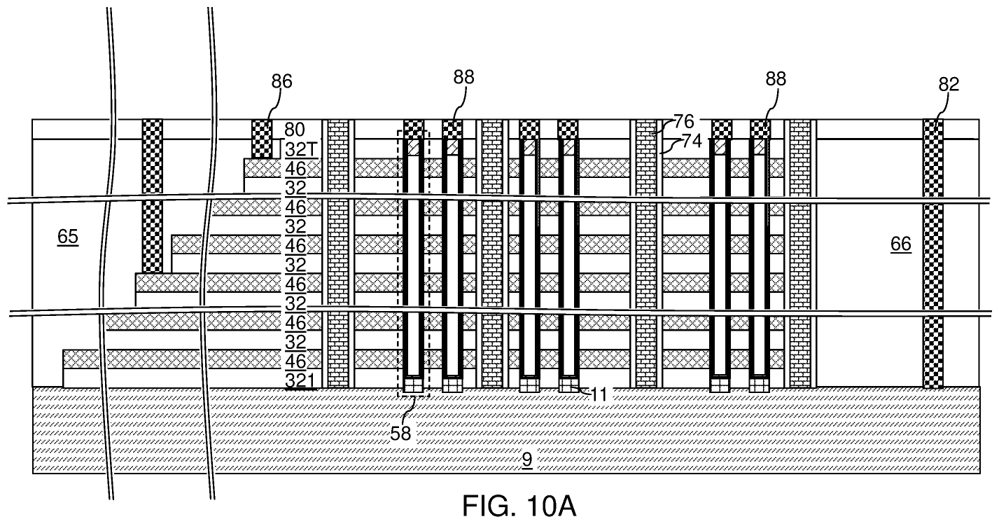

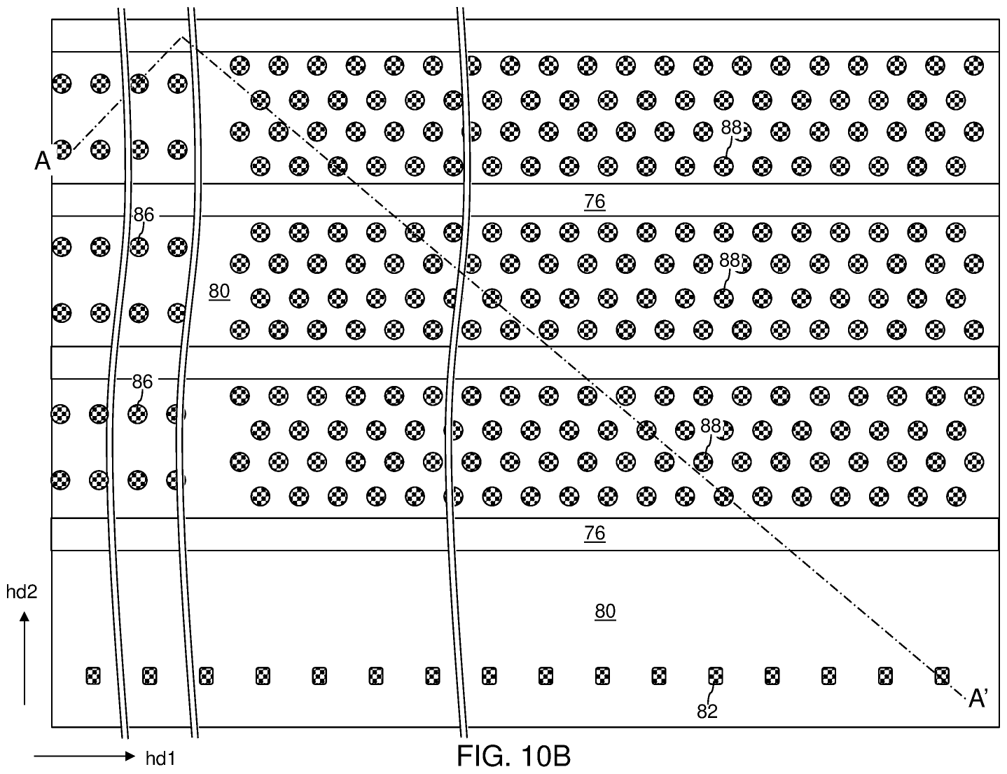

Referring to FIGS. 10A and 10B, a photoresist layer (not shown) can be applied over the contact-level dielectric layer 80, and can be lithographically patterned to form openings therethrough. An anisotropic etch process can be performed to transfer the pattern of the openings in the photoresist layer through the contact-level dielectric layer 80 and optionally through the dielectric material portions (65, 66). Various contact via cavities can be formed through the contact-level dielectric layer 80 and the dielectric material portions (65, 66). The photoresist layer can be subsequently removed, for example, by ashing.

At least one conductive material, such as a combination of a metallic barrier material and a metal fill material, can be deposited in the contact via cavities. Excess portions of the at least one conductive material can be removed from above the horizontal plane including the top surface of the contact-level dielectric layer 80 by a planarization process, which may employ a recess etch process and/or a chemical mechanical polishing process. Remaining portions of the at least one conductive material that fill the various contact via cavities constitute various contact via structures (86, 88, 82). The various contact via structures (86, 88, 82) may comprise layer contact via structures 86 vertically extending through the contact-level dielectric layer 80 and the retro-stepped dielectric material portion 65 and contacting a respective one of the electrically conductive layers 86, drain contact via structures 88 contacting a top surface of a respective one of the drain regions 63, and through-memory-level via structures 82 that vertically extend through the contact-level dielectric layer 80 and the field dielectric material portion 66 and contacting a top surface of the carrier substrate 9.

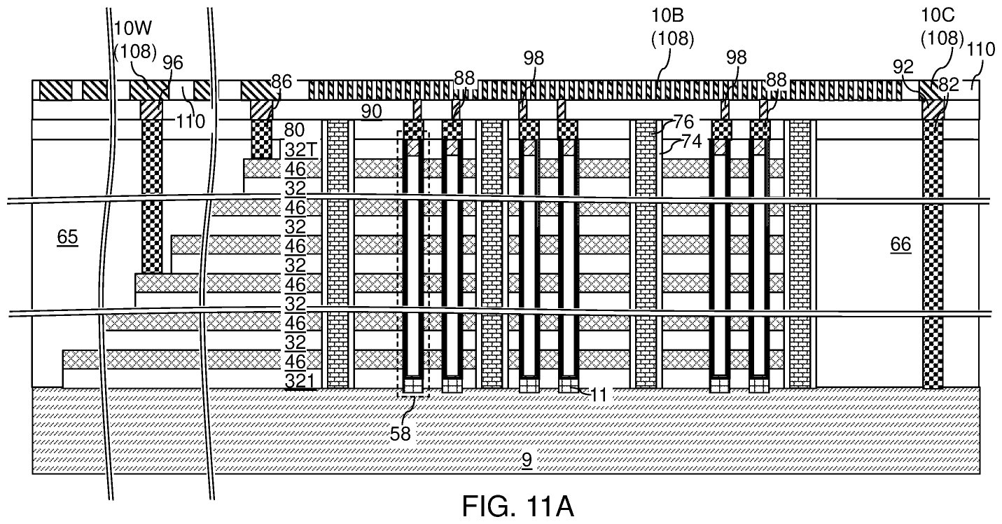

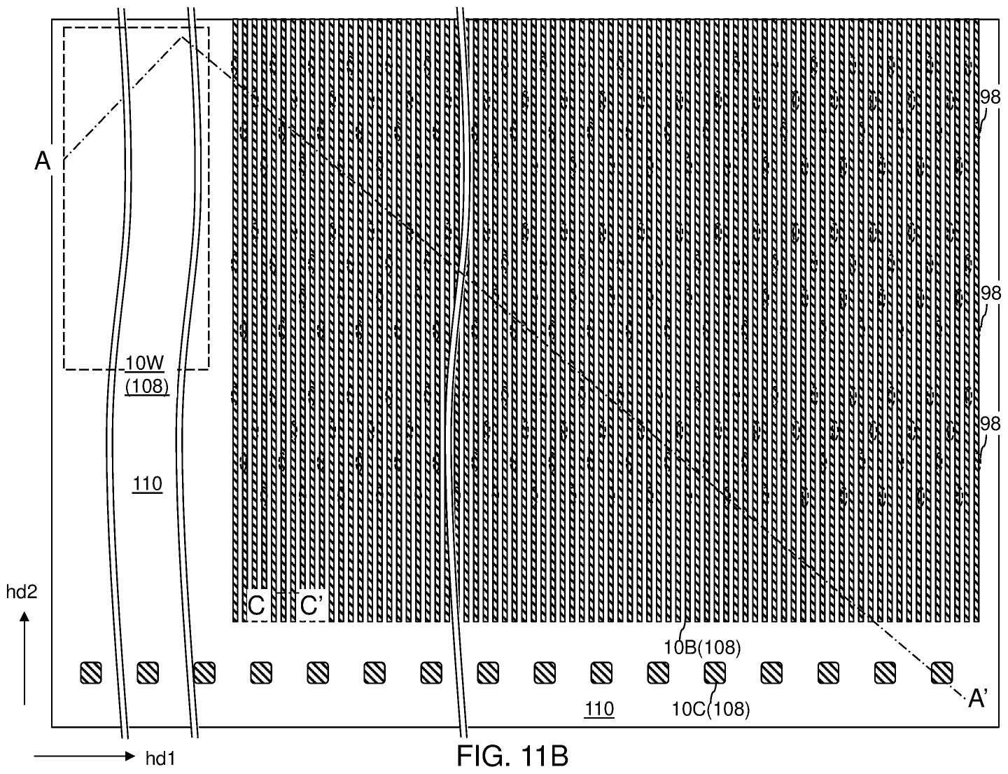

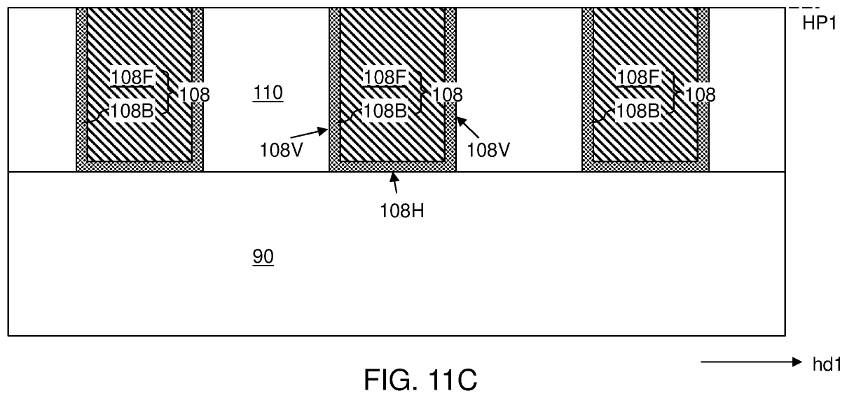

Referring to FIGS. 11A-11C, a connection-level dielectric layer 90 can be formed over the contact-level dielectric layer 80 by deposition of a dielectric material such as silicon oxide. Connection via structures (98, 96, 92) can be formed through the connection-level dielectric layer 90 on a respective one of the contact via structures (86, 88, 82). For example, bit-line-connection via structures 98 can be formed on the drain contact via structures 88, layer connection via structures 96 can be formed on the layer contact via structures 86, and peripheral connection via structures 92 that are formed on through-memory-level via structures 82. In an alternative embodiment, the peripheral connection via structures 92 can be located over the retro-stepped dielectric material portion 65 and the through-memory-level via structures 82 may extend through the retro-stepped dielectric material portion 65 to the side of the alternating stack (32, 46) if the field dielectric material portion 66 is omitted.

A first dielectric material layer 110 can be formed over the connection-level dielectric layer 90. The first dielectric material layer 110 includes an interconnect-level dielectric (ILD) material, such as undoped silicate glass (i.e., silicon oxide), a doped silicate glass, or porous or non-porous organosilicate glass. The thickness of the first dielectric material layer 110 may be in a range from 50 nm to 300 nm, although lesser and greater thicknesses may also be employed.

First conductive interconnect structures 108 can be formed in the first dielectric material layer 110. In one embodiment, the first conductive interconnect structures 108 may comprise first-line-level metal lines. In this case, the first dielectric material layer 110 can be a first line-level dielectric layer, i.e., a dielectric material layer that embeds the first-line-level metal lines therein. In one embodiment, the first conductive interconnect structures 108 may include bit lines 10B, first word-line-connection metal lines 10W, and first peripheral-connection metal lines 10C. In this case, the first dielectric material layer 110 may be referred to as a bit-line-level dielectric layer, i.e., a dielectric layer that embeds the bit lines 10B.

The bit lines 10B can be parallel to each other, and can laterally extend along a horizontal direction that is perpendicular to the lengthwise direction of the isolation trench fill structures (74, 76). For example, if the isolation trench fill structures (74, 76) laterally extend along the first horizontal direction hd1, the bit lines 10B may laterally extend along the second horizontal direction (e.g., bit line direction) hd2. In one embodiment, the bit lines 10B are laterally spaced from each other along the first horizontal direction hd1 with a first pitch and laterally extend along the second horizontal direction hd2. Each bit line 10B can be electrically connected to a respective subset of the drain regions 63 through a respective subset of the drain contact via structures 88 and a respective subset of the bit-line-connection via structures 98. The first word-line-connection metal lines 10W can be formed on the layer connection via structures 96. The first peripheral-connection metal lines 10C can be formed on the peripheral connection via structures 92.

Referring to FIG. 11C, each of the first conductive interconnect structures 108 may comprise a first metallic barrier liner 108B and a first metal fill material portion 108F laterally surrounded by the first metallic barrier liner 108B. The first conductive interconnect structures 108 can be formed, for example, by a damascene process which includes forming line cavities through the first dielectric material layer 110, filling the liner cavities with a first continuous metallic barrier liner layer and a first metal fill material layer including a first metal fill material, and performing a planarization process (such as a chemical mechanical polishing process) to remove portions of the first continuous metallic barrier liner layer and the first metal fill material of the first metal fill material layer from above a first horizontal plane HP1 including a top surface of the first dielectric material layer 110. In one embodiment, the first continuous metallic barrier liner layer may be formed by a conformal deposition process (such as a chemical vapor deposition process) and/or by a non-conformal deposition process (such as a physical vapor deposition process). Each remaining portion of the first continuous metallic barrier liner layer constitutes a first metallic barrier liner 108B, and each remaining portion of the first metal fill material layer constitutes a first metal fill material portion 108F.

In one embodiment, each first conductive interconnect structure 108 can be embedded in the first dielectric material layer 110. Each first metal fill material portion 108F and each first metal fill material portion 108F may have a top surface within the first horizontal plane HP1, which includes the top surface of the first dielectric material layer 110.

In one embodiment, the first metallic barrier liners 108B comprise and/or consist essentially of at least one conductive material layer selected from a titanium layer, a tantalum layer, a titanium nitride layer or a tantalum nitride layer. The first metal fill material of the first metal fill material portions 108F comprises copper at an atomic percentage greater than 95%, and/or greater than 99%, and/or greater than 99.9% (e.g., pure copper or copper alloyed with less than 5 atomic percent of Al and/or Si).

Each of the first metallic barrier liners 108B may comprise a horizontally-extending portion 108H and vertically-extending portions 108V that are adjoined to a respective peripheral region of the horizontally-extending portion 108H. In one embodiment, upper regions of the vertically-extending portions of the first metallic barrier liner 108B may have a uniform, or substantially uniform, lateral thickness, which may be in a range from 3 nm to 30 nm, such as from 6 nm to 15 nm, although lesser and greater heights may also be employed. The height of each first conductive interconnect structure 108 may be in a range from 50 nm to 300 nm, although lesser and greater thicknesses may also be employed.

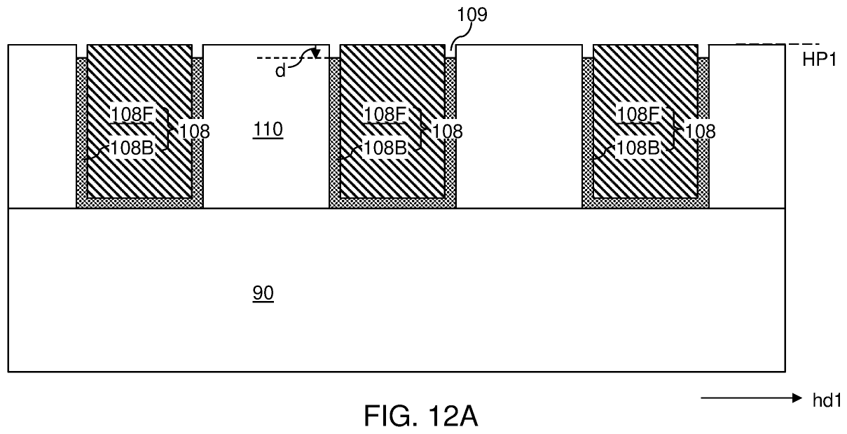

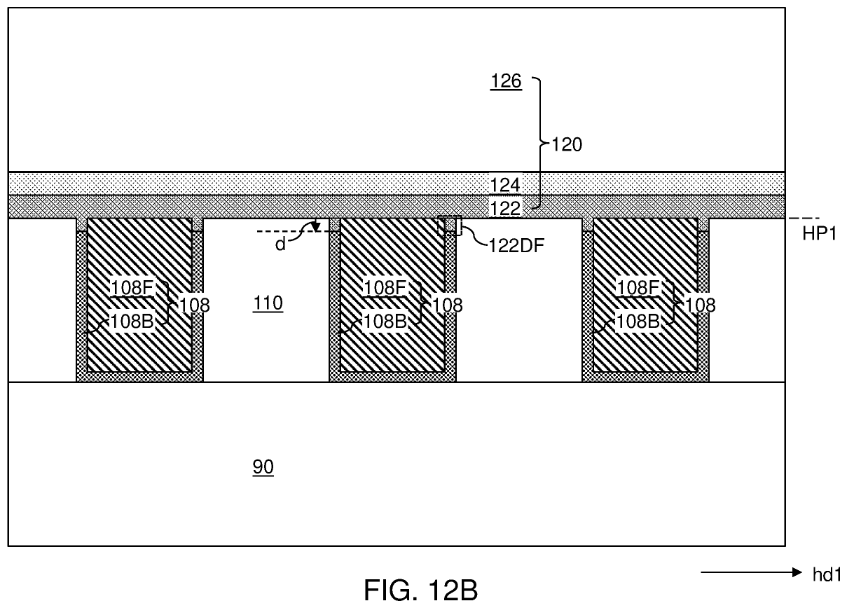

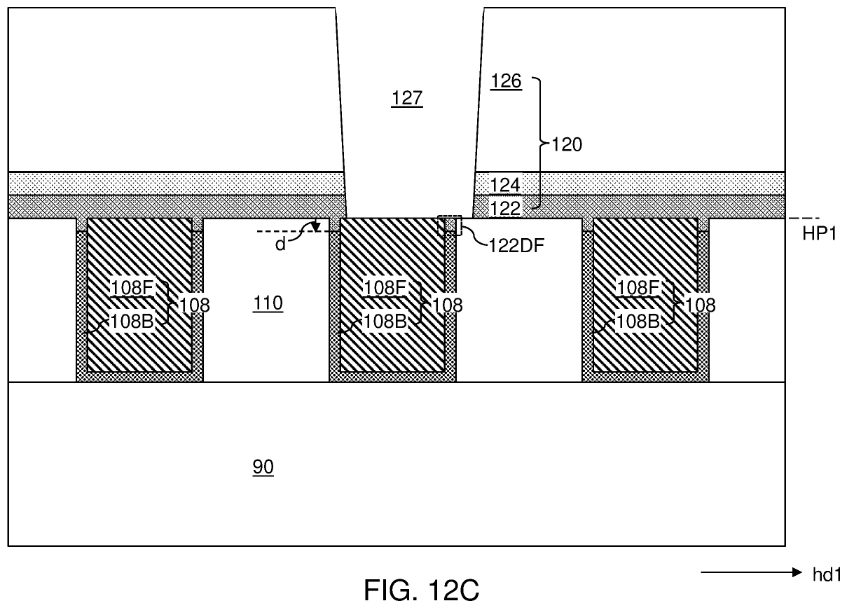

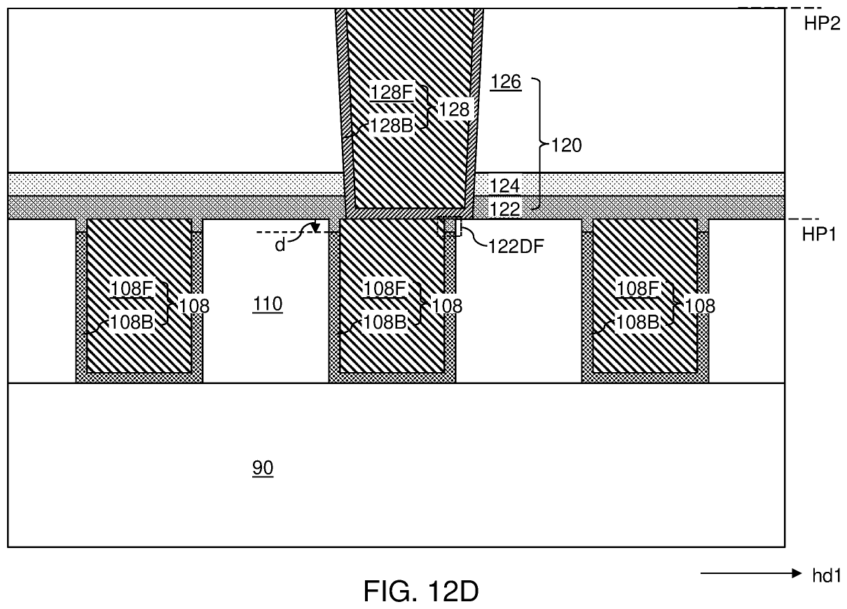

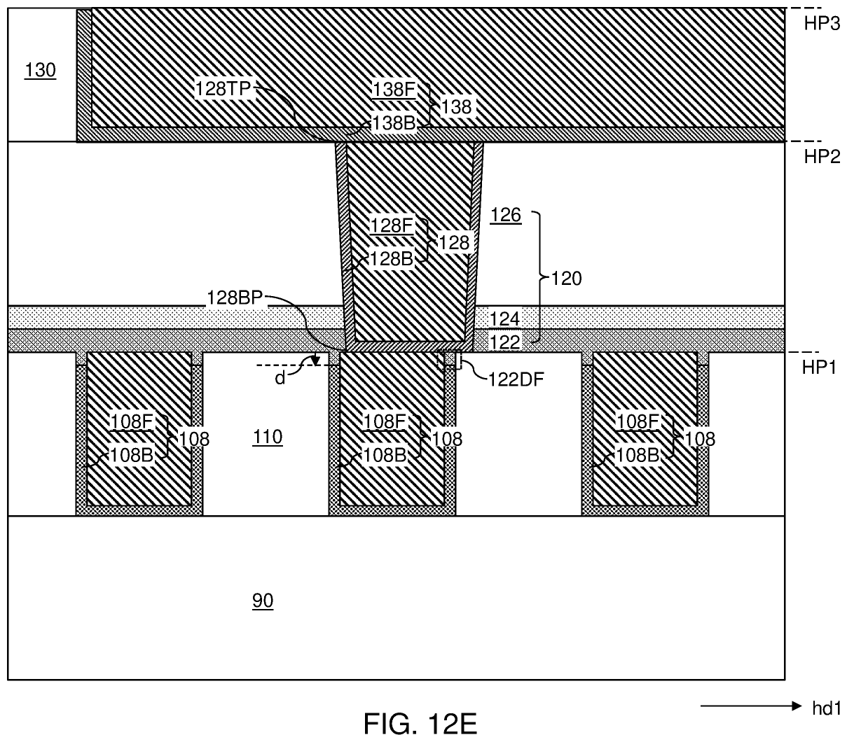

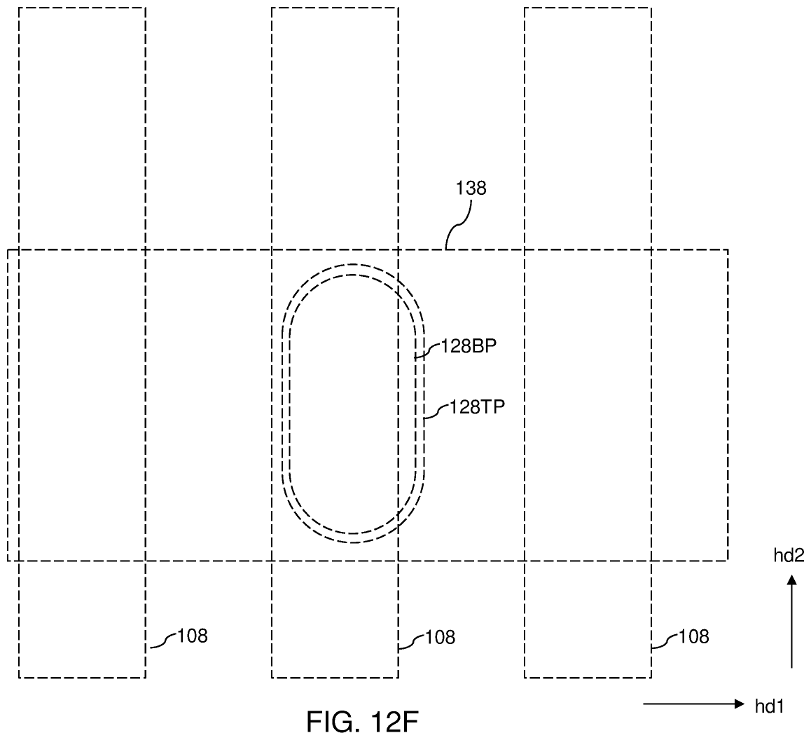

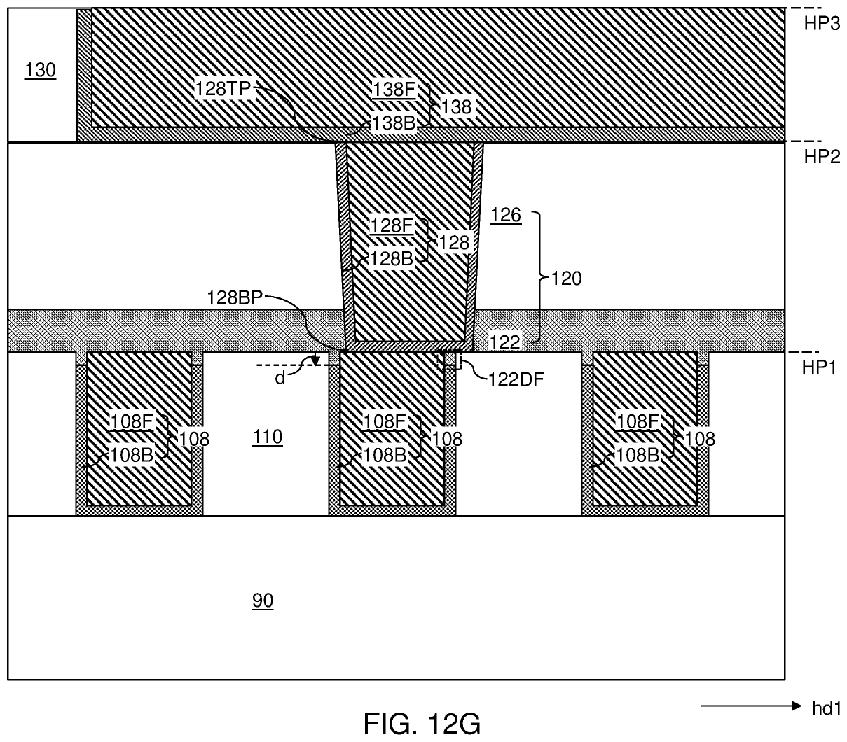

FIGS. 12A-12E are sequential vertical cross-sectional views of a region of the exemplary structure during formation of second conductive interconnect structure 128 (such as metal via structures) and third conductive interconnect structures 138 (such as second-line-level metal lines) according to an embodiment of the present disclosure. The second conductive interconnect structure 128 may comprise a bit line contact via structure.

Referring to FIG. 12A, a selective etch process can be performed to etch the material of the first metallic barrier liners 108B selective to the materials of the first metal fill material portions 108F and the first dielectric material layer 110. In one embodiment, each top surface of the first metallic barrier liners 108B can be selectively recessed by performing a selective wet etch process employing a liquid etchant that etches the material of the first metallic barrier liner 108B selective to the materials of the first metal fill material portion 108F and the first dielectric material layer 110. For example, the selective etch process may comprise a wet etch process employing ammonium hydroxide (NH₄OH), hydrofluoric acid (HF), and/or phosphoric acid (H₃PO₄). The top surfaces of the first metallic barrier liners 108B can be selective etched and vertically recessed relative to the first metal fill material portion 108F and the first dielectric material layer 110. The top surfaces of the first metallic barrier liners 108B can be recessed below the first horizontal plane HP1 by a recess distance d, which may be in a range from 2 nm to 50 nm, such as from 4 nm to 25 nm, although lesser and greater recess distances d may also be employed. A moat-shaped divot (i.e., trench) 109 can be formed between each first metal fill material portion 108F and the first dielectric material layer 110. In one embodiment, each moat-shaped divot 109 may have a uniform width throughout. The uniform width of the moat-shaped divots 109 may be in a range from 3 nm to 30 nm. Each first metallic barrier liner 108B laterally surrounds a respective first metal fill material portion 108F, and has a respective top surface below the first horizontal plane HP1.

Referring to FIG. 12B, a dielectric diffusion barrier material can be conformally deposited to form a dielectric diffusion barrier layer 122 over the first conductive interconnect structure 108 and the first dielectric material layer 110. The dielectric diffusion barrier material of the dielectric diffusion barrier layer 122 comprises a dielectric material that is effective in blocking diffusion of fluorine. In one embodiment, the dielectric diffusion barrier layer 122 comprises, and/or consists essentially of, a nitrogen-containing diffusion barrier material selected from silicon nitride, aluminum nitride, silicon carbonitride or silicon oxynitride including nitrogen atoms at a higher atomic percentage than oxygen atoms. In one embodiment, the dielectric diffusion barrier layer 122 may comprise and/or may consist essentially of silicon nitride. The dielectric diffusion barrier layer 122 may be deposited by chemical vapor deposition or atomic layer deposition. The thickness of a horizontally-extending portion of the dielectric diffusion barrier layer 122 overlying top surfaces of the first metal fill material portions 108F may be in a range from 10 nm to 60 nm, such as from 20 nm to 40 nm, although lesser and greater thicknesses may also be employed.

According to an aspect of the present disclosure, the dielectric diffusion barrier layer 122 overlies the first conductive interconnect structures 108 and the first dielectric material layer 110, and comprises downward-protruding divot-fill dielectric portions 122DF contacting the top surface of the first metallic barrier liner 108B and filling a respective moat-shaped divot 109. In one embodiment, at least one of the downward-protruding divot-fill dielectric portions 122DF may have an annular configuration and may laterally surround an upper portion of a respective one of the first metal fill material portions 108F.

In one embodiment, each sidewall of the first metal fill material portions 108F may comprise a respective lower sidewall segment in contact with a respective inner sidewall of a first metallic barrier liner 108B, and a respective upper sidewall segment in contact with a respective inner sidewall of a downward-protruding divot-fill dielectric portion 122DF. In one embodiment, the entirety of each sidewall of the first metal fill material portions 108F may be in contact with a respective inner sidewall of a first metallic barrier liner 108B and with a respective inner sidewall of a downward-protruding divot-fill dielectric portion 122DF. In one embodiment, vertically-extending portions of the first metallic barrier liners 108B may have a first thickness, and the downward-protruding divot-fill dielectric portions 122DF may have the same thickness, i.e., the first thickness.

Optionally, an etch stop dielectric layer 124, such as a silicon carbonitride layer, may be formed on a top surface of the dielectric diffusion barrier layer 122, which may comprise a silicon nitride layer. The thickness of the etch stop dielectric layer 124 may be in a range from 10 nm to 60 nm, such as from 20 nm to 40 nm, although lesser and greater thicknesses may also be employed. The etch stop dielectric layer 124 may comprise a cap layer having a lower capacitance than the dielectric diffusion barrier layer 122 to reduce interlayer capacitance between vertically separated electrically conductive layers.

A second dielectric material layer 126 can be subsequently formed over the dielectric diffusion barrier layer 122 and the optional etch stop dielectric layer 124. The second dielectric material layer 126 includes an interconnect-level dielectric (ILD) material, such as undoped silicate glass, a doped silicate glass, or porous or non-porous organosilicate glass. The thickness of the second dielectric material layer 126 may be in a range from 50 nm to 300 nm, although lesser and greater thicknesses may also be employed. The combination of the dielectric diffusion barrier layer 122, the optional etch stop dielectric layer 124, and the second dielectric material layer 126 is herein referred to as a via-level dielectric layer 120.

Referring to FIG. 12C, a photoresist layer (not shown) can be applied over the via-level dielectric layer 120, and can be lithographically patterned to form discrete openings that overlie a respective one of the first conductive interconnect structures 108 (which may include the bit lines 10B, the first word-line-connection metal lines 10W, and/or the first peripheral-connection metal lines 10C). An anisotropic etch process can be performed to etch portions of the via-level dielectric layer 120 that are not masked by the photoresist layer. The anisotropic etch process can sequentially etch through the second dielectric material layer 126, the optional etch stop dielectric layer 124, and unmasked portions of the dielectric diffusion barrier layer 122 that overlie the first horizontal plane HP1. For example, the anisotropic etch process may comprise a first reactive ion etch step that etches the material of the second dielectric material layer 126 selective to the material of the optional etch stop dielectric layer 124 (or the dielectric diffusion barrier layer 122), an optional reactive ion etch step that etches the material of the etch stop dielectric layer 124 selective to the material of the dielectric diffusion barrier layer 122, and a second reactive ion etch step that etches the material of the dielectric diffusion barrier layer 122 selective to the material of the first metal fill material portions 108F (which may be a copper-based material composed primarily of copper). In one embodiment, the duration of the second reactive ion etch step may be determined by an endpoint detection scheme, which detects exposure of the metallic surfaces of the first metal fill material portions 108F and terminates the second reaction ion etch step to eliminate or minimize additional etching of the dielectric diffusion barrier layer 122. In this case, a horizontal surface of the dielectric diffusion barrier layer 122 may be formed within the first horizontal plane HP1 that includes the top surface of the first dielectric material layer 110.

Vertically-extending cavities 127 can be formed through the second dielectric material layer 126, the optional etch stop dielectric layer 124, and the dielectric diffusion barrier layer 122 underneath the openings in the photoresist layer. The photoresist layer can be subsequently removed, for example, by ashing. The vertically-extending cavities 127 may comprise via cavities. For example, if a first conductive interconnect structure 108 comprises a bit line 10B having a width along the first horizontal direction hd1, an overlying vertically-extending cavity 127 may be a bit-line-contact via cavity.

According to an aspect of the present disclosure, a segment of a top surface of a first metal fill material portion 108F is exposed underneath each vertically-extending cavity 127. A segment of a downward-protruding divot-fill dielectric portion 122DF may also optionally be exposed underneath each vertically-extending cavity 127. The width of each vertically-extending cavity 127 may be less than, the same as or greater than the width of an underlying first conductive interconnect structure 108. In one embodiment, the width of a vertically-extending cavity 127 may be greater than the width of an underlying first conductive interconnect structure 108, or the vertically-extending cavity 127 may be formed with an overlay error along a widthwise direction of the underlying first conductive interconnect structure 108. In this case, a top surface segment of the downward-protruding divot-fill dielectric portion 122DF and the first dielectric material layer 110 may be exposed underneath such a vertically-extending cavity 127.

Referring to FIG. 12D, second conductive interconnect structures 128 can be formed in the vertically-extending cavities 127. The vertically-extending cavities 127 can be filled with a second continuous metallic barrier liner layer and a second metal fill material layer. In one embodiment, the second continuous metallic barrier liner layer may be formed by a conformal deposition process (such as a chemical vapor deposition process) and/or by a non-conformal deposition process (such as a physical vapor deposition process). In one embodiment, the second continuous metallic barrier liner layer comprises and/or consists essentially of at least one material layer selected from a titanium layer, a tantalum layer, a titanium nitride layer, a tantalum nitride layer, a tungsten nitride layer, or a molybdenum nitride layer. The second metal fill material layer comprises a metal fill material. In one embodiment, the second metal fill material layer comprises a metal that can be deposited by decomposition of a fluorine-containing metal precursor. For example, the second metal fill material layer comprises an elemental metal selected from tungsten, cobalt, ruthenium, titanium, tantalum, and molybdenum. In one embodiment, the second metal fill material layer may be formed by decomposition of tungsten hexafluoride, cobalt hexafluoride, ruthenium hexafluoride, titanium tetrafluoride, tantalum pentafluoride, or molybdenum hexafluoride.

A planarization process (such as a chemical mechanical polishing process) can be performed to remove portions of the second continuous metallic barrier liner layer and the second metal fill material layer from above a second horizontal plane HP2 including a top surface of the second dielectric material layer 120. Each remaining portion of the second continuous metallic barrier liner layer constitutes a second metallic barrier liner 128B, and each remaining portion of the second metal fill material layer constitutes a second metal fill material portion 128F. Each of the second conductive interconnect structures 128 may comprise a second metallic barrier liner 128B and a second metal fill material portion 128F laterally surrounded by the second metallic barrier liner 128B. Each second conductive interconnect structure 128 can be embedded in the via-level dielectric layer 120, which may include a layer stack of a second dielectric material layer 126, an optional etch stop dielectric layer 124, and a dielectric diffusion barrier layer 122. Each second metal fill material portion 128F and each second metal fill material portion 128F may have a top surface within the second horizontal plane HP2, which includes the top surface of the second dielectric material layer 126.

In one embodiment, the second metallic barrier liners 128B comprise and/or consist essentially of at least one material layer selected from a titanium layer, a tantalum layer, a titanium nitride layer, a tantalum nitride layer, a tungsten nitride layer, or a molybdenum nitride layer. In one embodiment, second metal fill material portions 128F comprise and/or consist essentially of an elemental metal selected from tungsten, cobalt, ruthenium, titanium, tantalum, and molybdenum. Fluorine atoms may be present within the second metal fill material portions 128F at an atomic percentage less than 1%, and typically less than 0.1% and/or less than 100 parts per million.

In one embodiment, at least one of the second conductive interconnect structures 128 comprises a second metallic barrier liner 128B having a bottom surface within the first horizontal plane HP1, having a top surface located within a second horizontal plane HP2, and contacting a top surface of a respective first metal fill material portion 108F, and a second metal fill material portion 128F that is laterally surrounded by the second metallic barrier liner 128B and having a top surface within the second horizontal plane HP2.

Generally, each second conductive interconnect structure 128 may be formed through the dielectric diffusion barrier layer 122 and the second dielectric material layer 126 and directly on a segment of a top surface of a respective first metal fill material portion 108F. In one embodiment, at least one of the second conductive interconnect structures 128 may be formed directly on a segment of the top surface of the first dielectric material layer 110 and/or the downward-protruding divot-fill dielectric portion 122DF. In one embodiment, at least one of the second conductive interconnect structure 128 may be embedded in the dielectric diffusion barrier layer 122 and the second dielectric material layer 126, and may contact a segment of a top surface of a respective first metal fill material portion 108F.

In one embodiment, at least one of the second conductive interconnect structures 128 may comprise a respective metal via structure having a lesser lateral extent along the second horizontal direction hd2, which can be lengthwise direction of a respective underlying first conductive interconnect structure 108, than the respective first conductive interconnect structure 108. In one embodiment, at least one of the second conductive interconnect structures 128 may have a respective bottom surface that is in direct contact with a top surface of a respective first metal fill material portion 108F and is in direct contact with a top surface of a segment of a respective downward-protruding divot-fill dielectric portion 122DF. The downward-protruding divot-fill dielectric portion 122DF protects the first metallic barrier liner 108B from fluorine attack due to fluorine diffusion out of the second metal fill portion 128F through the second metallic barrier liner 128B.

Referring to FIGS. 12E and 12F, a third dielectric material layer 130 can be formed over the second dielectric material layer 120. The third dielectric material layer 130 includes an interconnect-level dielectric (ILD) material such as undoped silicate glass, a doped silicate glass, or porous or non-porous organosilicate glass. The dielectric material of the third dielectric material layer 130 may be the same as or may be different from the dielectric material of the second dielectric material layer 120. The thickness of the third dielectric material layer 130 may be in a range from 50 nm to 300 nm, although lesser and greater thicknesses may also be employed.

Third conductive interconnect structures 138 can be formed in the third dielectric material layer 130. In one embodiment, the third conductive interconnect structures 138 may comprise second-line-level metal lines. In this case, the third dielectric material layer 130 can be a third line-level dielectric layer, i.e., a dielectric material layer that embeds the second-line-level metal lines therein. The third conductive interconnect structures 138 can be formed, for example, by forming line cavities through the third dielectric material layer 130, by filling the liner cavities with a third continuous metallic barrier liner layer and a third metal fill material layer including a third metal fill material, and by performing a planarization process (such as a chemical mechanical polishing process) to remove portions of the third continuous metallic barrier liner layer and the third metal fill material of the third metal fill material layer from above a third horizontal plane HP3 including a top surface of the third dielectric material layer 130. In one embodiment, the third continuous metallic barrier liner layer may be formed by a conformal deposition process (such as a chemical vapor deposition process) and/or by a non-conformal deposition process (such as a physical vapor deposition process). Each remaining portion of the third continuous metallic barrier liner layer constitutes a third metallic barrier liner 138B, and each remaining portion of the third metal fill material layer constitutes a third metal fill material portion 138F. In one embodiment, a periphery 128BP of a bottom surface of a second conductive interconnect structure 128 may be in contact with a top surface of a first metal fill material portion 108F, a top surface of a segment of the downward-protruding divot-fill dielectric portion 122DF, and a segment the top surface of the first dielectric material layer 110. A periphery 128TP of a top surface of the second conductive interconnect structure 128 may be laterally offset outward from the periphery 128BP of the bottom surface of the second conductive interconnect structure 128.

In the previous embodiment illustrated in FIGS. 12C, 12D and 12E, the second conductive interconnect structures 128 and the third conductive interconnect structures 138 are formed in separate steps using single damascene formation steps. In an alternative embodiment, second conductive interconnect structures 128 and the third conductive interconnect structures 138 can be formed during a single deposition step using a dual damascene process. In the dual damascene process, the third dielectric material layer 130 is deposited on the via-level dielectric material layer 120, followed by etching the vertically extending cavities 127 and the line cavities through the via-level dielectric material layer 120 and the third dielectric material layer 130, followed by depositing the electrically conductive material (e.g., combined barrier liner 128B/138B and the combined conductive fill material portions 128F/138F) into the vertically extending cavities 127 and the line cavities, followed by planarizing the electrically conductive material. Furthermore, in the previous embodiment, the second conductive interconnect structures 128 located in the vertically extending cavities 127 are illustrated in FIG. 12F as having an elliptical horizontal cross sectional shape. However, in alternative embodiments, the second conductive interconnect structures 128 may have a circular horizontal cross sectional shape. Furthermore, second conductive interconnect structures 128 contacting the first word-line-connection metal lines 10W and/or the first peripheral-connection metal lines 10C may have a circular horizontal cross sectional shape even if the second conductive interconnect structures 128 contacting the bit lines 10B have the elliptical horizontal cross sectional shape.

Referring to FIG. 12G, an alternative configuration of the exemplary structure is illustrated formation of second-line-level metal lines, i.e., after formation of third conductive interconnect structures 138. The alternative configuration of the exemplary structure illustrated in FIG. 12G may be derived from the exemplary structure illustrated in FIGS. 12E and 12F by omitting formation of the optional etch stop dielectric layer 124. In this alternative embodiment, the thickness of the dielectric diffusion barrier layer 122 may be the same as a sum of the thickness of the etch stop dielectric layer 124 and the dielectric diffusion barrier layer 122 shown in FIGS. 12B to 12E of the previous embodiment.

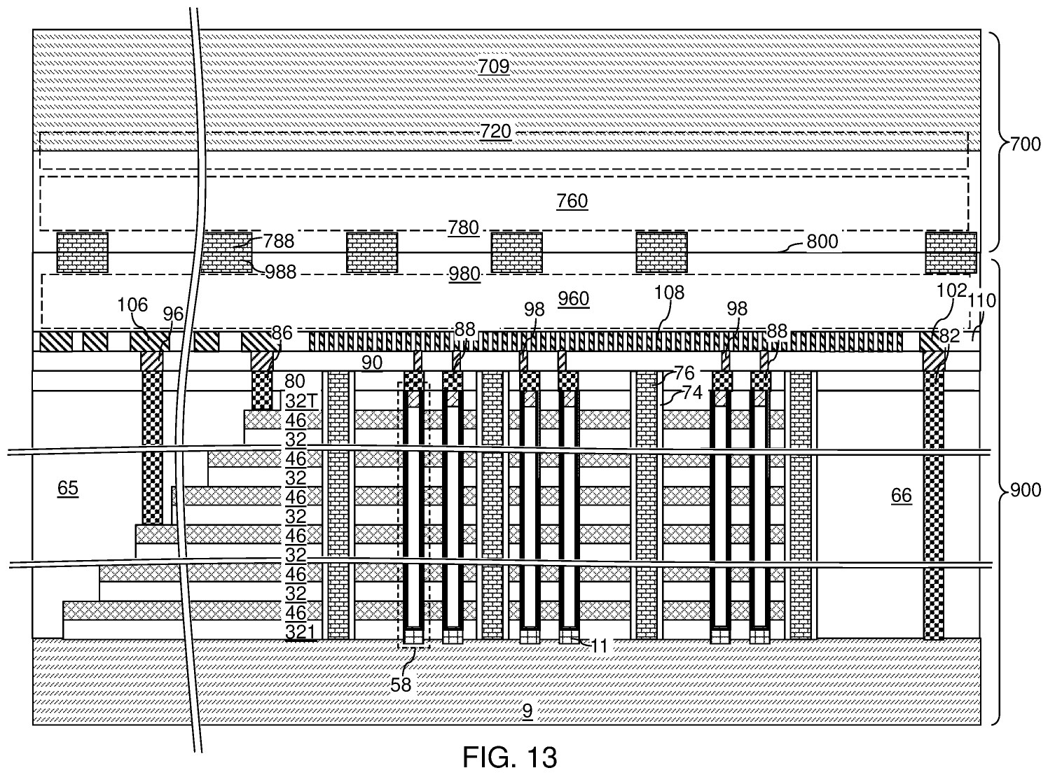

Referring to FIG. 13, additional dielectric material layers and additional conductive interconnect structures can be formed as needed over the third dielectric material layer 130 and the third conductive interconnect structures 138. The additional dielectric material layers may include at least one via-level dielectric layer, at least one additional line-level dielectric layer, and/or at least one additional line-and-via-level dielectric layer. The additional conductive interconnect structures may comprise metal via structures, metal line structures, and/or integrated metal line-and-via structures. The set of the via-level dielectric material layer 120, the third dielectric material layer 130, and any additional dielectric material layer that is formed above the first dielectric material layer 110 is herein referred to as upper dielectric material layers 960. The second conductive interconnect structures 128, the third conductive interconnect structures 138, and any additional conductive interconnect structures are collectively referred to as upper dielectric material layers 960.

Metal bonding pads, which are herein referred to as upper bonding pads 988, may be formed at the topmost level of the upper dielectric material layers 960. The upper bonding pads 988 may be electrically connected to the upper conductive interconnect structures 980 and various nodes of the three-dimensional memory array including the alternating stacks of insulating layers 32 and electrically conductive layers 46 and the memory opening fill structures 58. A memory die 900 is thus formed.

The set of all conductive interconnect structures formed in, or above, the contact-level dielectric layer 80 is herein referred to as memory-side conductive interconnect structures (88, 86, 82, 98, 96, 92, 108, 980). The set of all dielectric material layers formed above the alternating stacks (32, 46) is herein referred to as memory-side dielectric material layers (80, 90, 110, 960). The memory-side dielectric material layers (80, 90, 110, 960) are formed over the alternating stacks (32, 46). The memory-side conductive interconnect structures (88, 86, 82, 98, 96, 92, 108, 980) comprise bit lines 108. The memory-side bonding pads 988 can be embedded within the memory-side dielectric material layers (80, 90, 110, 960), and specifically, within the topmost layer among the memory-side dielectric material layers (80, 90, 110, 960). The memory-side bonding pads 988 can be electrically connected to the memory-side conductive interconnect structures (88, 86, 82, 98, 96, 92, 108, 980).

In one embodiment, the memory die 900 may comprise: a three-dimensional memory array underlying the first dielectric material layer 110 and comprising an alternating stack (32, 46) of insulating layers 32 and electrically conductive layers 46, a two-dimensional array of memory openings 49 vertically extending through the alternating stack (32, 46), and a two-dimensional array of memory opening fill structures 58 located in the two-dimensional array of memory openings 49 and comprising a respective vertical stack of memory elements and a respective vertical semiconductor channel 60; and a two-dimensional array of contact via structures (such as the drain contact via structures 88) overlying the three-dimensional memory array and electrically connected to a respective one of the vertical semiconductor channels 60, wherein a first conductive interconnect structure 108 is electrically connected to a respective subset of the contact via structures (such as the drain contact via structures 88) within the two-dimensional array of contact via structures. In one embodiment, the first conductive interconnect structure 108 may be a bit line 10B.

Additionally, a logic die 700 can be provided. The logic die 700 includes a logic-side substrate 709, a peripheral circuit 720 located on the logic-side substrate 709 and comprising logic-side semiconductor devices (such as field effect transistors), logic-side conductive interconnect structures 780 embedded within logic-side dielectric material layers 760, and logic-side bonding pads 778. The peripheral circuit 720 can be configured to control operation of the memory array within the memory die 900. Specifically, the peripheral circuit 720 can be configured to drive various electrical components within the memory array including, but not limited to, the electrically conductive layers 46, the drain regions 53, and a source structure to be subsequently formed. The peripheral circuit 720 can be configured to control operation of the vertical stack of memory elements in the memory array in the memory die 900.

The logic die 700 can be attached to the memory die 900, for example, by bonding the logic-side bonding pads 778 to the memory-side bonding pads 978. The bonding between the memory die 900 and the logic die 700 may be performed employing a wafer-to-wafer bonding process in which a two-dimensional array of memory dies 900 is bonded to a two-dimensional array of logic dies 700, by a die-to-bonding process, or by a die-to-die bonding process. The logic-side bonding pads 788 within each logic die 700 can be bonded to the memory-side bonding pads 988 within a respective memory die 900 at a bonding interface 800.

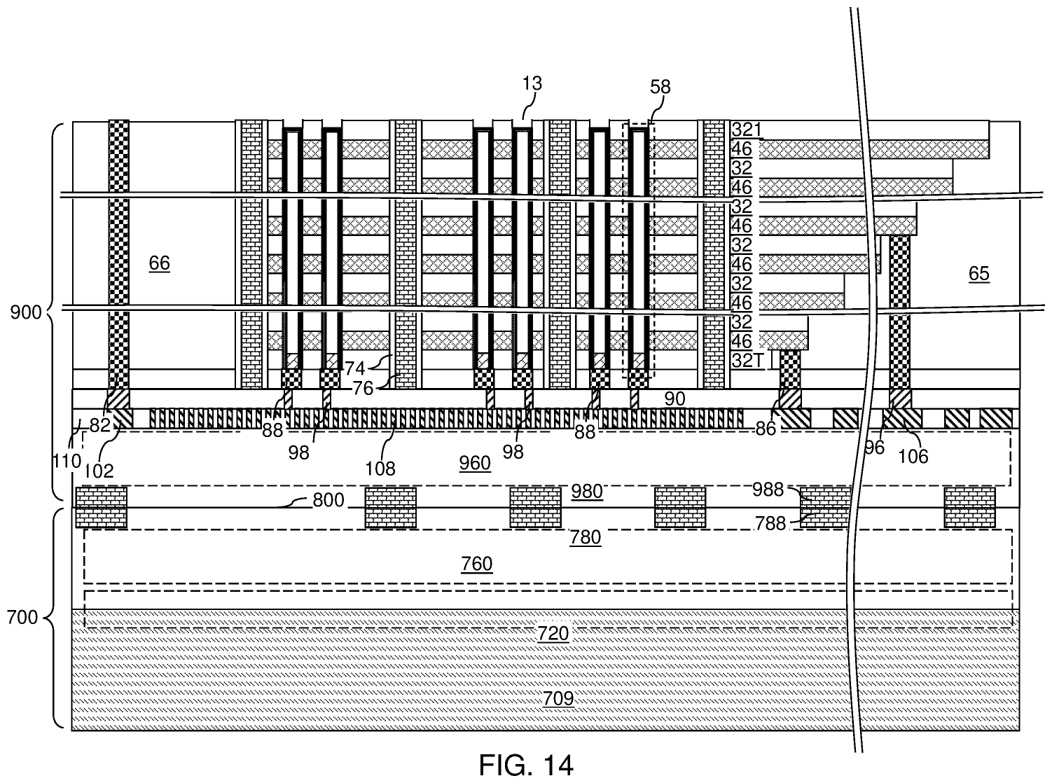

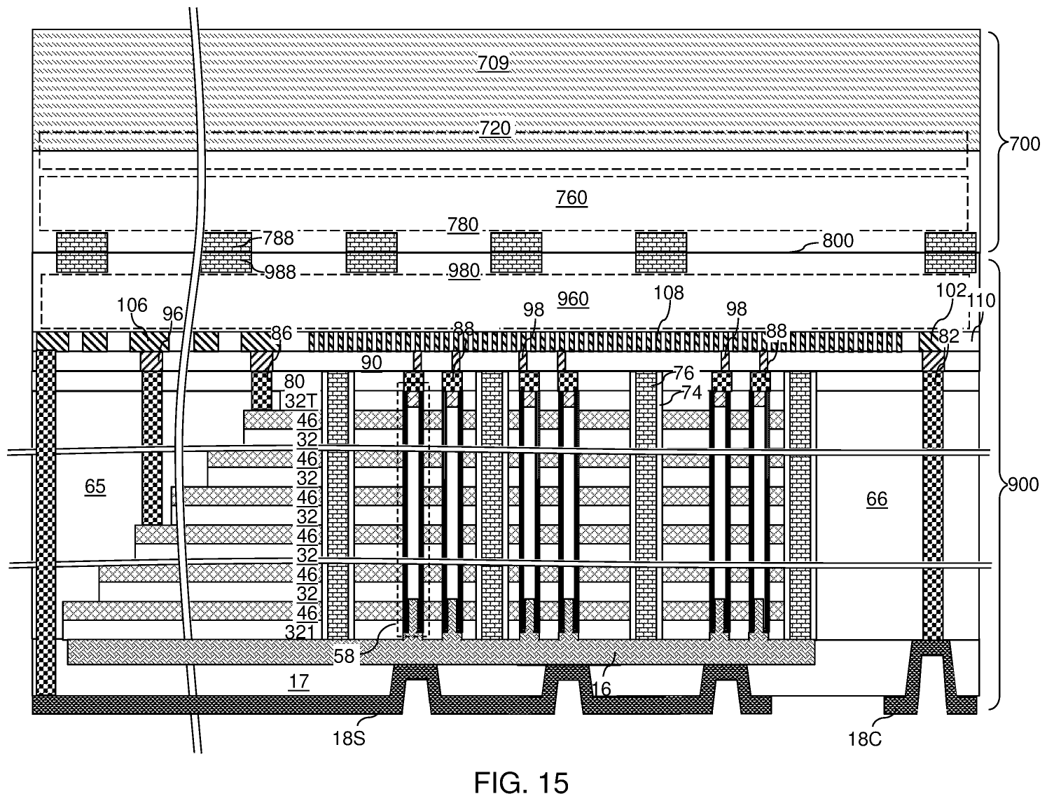

Referring to FIG. 14, the carrier substrate 9 can be removed, for example, by grinding, polishing, cleaving, an isotropic etch process, and/or an anisotropic etch process. The bottom surface of the most proximal insulating layer 321 within each alternating stack (32, 46) of insulating layers 32 and electrically conductive layers 46 can be physically exposed. In case an etch process is employed as a last processing step for removing the carrier substrate 9 selective to the material of the most proximal insulating layer 321 and if the sacrificial pillar structures 11 comprise a semiconductor material, the sacrificial pillar structures 11 can be removed during removal of the carrier substrate 9. Alternatively, a selective etch process can be performed to remove the sacrificial pillar structures 11 selective to the materials of the insulating layers 321 and the memory films 50. A cavity 13 can be formed in each volume from which a sacrificial pillar structure 11 is removed. A bottom surface of a memory film 50 can be physically exposed to a respective cavity 13.

Referring to FIG. 15, an etch process can be performed to remove horizontally-extending portions of the memory films 50. End portions of the vertical semiconductor channels 60 can be physically exposed. A source layer 16 comprising a semiconductor material (e.g., polysilicon) can be deposited on the physically exposed end portions of the vertical semiconductor channels 60. Each source layer 16 may have a doping of the second conductivity type which is the opposite of the first conductivity type. In one embodiment, the atomic concentration of dopants of the second conductivity type in each source layer 16 may be in a range from 5.0×10¹⁸/cm³ to 2.0×10²¹/cm³.

At least one backside dielectric layer 17 can be subsequently deposited over the source layer(s) 16. Optionally, backside conductive interconnect structures (not shown) may be formed within the at least one backside dielectric layer 17. If present, the backside conductive interconnect structures may comprise backside metal line structures and backside metal via structures. Electrically conductive (e.g., metal and/or metal nitride) backside contacts (18S, 18C) can be formed on the backside of the at least one backside dielectric layer 17. The backside contacts (18S, 18C) may comprise source-side backside contact 18S that is electrically connected to the source layer 16, and connection backside contact 18C that is electrically connected to the through-memory-level via structures 82.

Referring to all drawings and according to various embodiments of the present disclosure, a device structure includes a first dielectric material layer 110, a first conductive interconnect structure 108 embedded in the first dielectric material layer 110 and including a first metallic barrier liner 108B and a first metal fill material portion 108F having a top surface within a first horizontal plane HP1, where the first metallic barrier liner 108 laterally surrounds the first metal fill material portion 108F and has a top surface below the first horizontal plane HP1 such that a moat-shaped divot 109 is located between the first metal fill material portion 108F and the first dielectric material layer 110, a divot-fill dielectric portion 122DF located in the moat-shaped divot 109 and contacting the top surface of the first metallic barrier liner 108B, a second dielectric material layer 126 overlying the first dielectric material layer 110, and a second conductive interconnect structure 128 embedded in the second dielectric material layer and contacting at least a segment of the top surface of the first metal fill material portion 108F.

In one embodiment, a bottom surface of the second conductive interconnect structure 128 is in direct contact with at least the segment of the top surface of the first metal fill material portion 108F and is in direct contact with at least a segment of a top surface of a segment of the downward-protruding divot-fill dielectric portion 122DF. In one embodiment, the top surface of the segment of the downward-protruding divot-fill dielectric portion 122DF and the top surface of the first dielectric material layer are 110 located in the first horizontal plane HP1.

In one embodiment, a bottom surface of the second conductive interconnect structure 128 is in contact with a segment of the top surface of the first dielectric material layer 110. In one embodiment, a periphery 128BP of a bottom surface of the second conductive interconnect structure 128 is in contact with at least a segment of the top surface of the first metal fill material portion 108F, at least a segment of a top surface of a segment of the downward-protruding divot-fill dielectric portion 122DF, and at least a segment of the top surface of the first dielectric material layer 110.

In one embodiment, the downward-protruding divot-fill dielectric portion 122DF has an annular configuration and laterally surrounds an upper portion of the first metal fill material portion 108F.

In one embodiment, each sidewall of the first metal fill material portion 108F comprises: a respective lower sidewall segment in contact within a respective inner sidewall of the first metallic barrier liner 108B; and a respective upper sidewall segment in contact with a respective inner sidewall of the downward-protruding divot-fill dielectric portion 122DF.

In one embodiment, vertically-extending portions of the first metallic barrier liner 108B have a first thickness; and the downward-protruding divot-fill dielectric portion 122DF has the first thickness.

In one embodiment, the second conductive interconnect structure 128 comprises: a second metallic barrier liner 128B having a bottom surface within the first horizontal plane HP1, having a top surface located within a second horizontal plane HP2, and contacting at least a segment of the top surface of the first metal fill material portion 108F; and a second metal fill material portion 128F that is laterally surrounded by the second metallic barrier liner 128B and having a top surface within the second horizontal plane HP2. In one embodiment, the second metallic barrier liner 128B comprises a titanium layer, a tantalum layer, a titanium nitride layer, a tantalum nitride layer, a tungsten nitride layer, or a molybdenum nitride layer; and the second metal fill material portion 128F comprises tungsten, cobalt, ruthenium, titanium, tantalum, or molybdenum.

In one embodiment, the first conductive interconnect structure 108 comprises a bit line 10B of a semiconductor device 900; and the second conductive interconnect structure 128 comprises a metal via structure.

In one embodiment, the first metallic barrier liner 108B comprises a titanium layer, a tantalum layer, a titanium nitride layer, or a tantalum nitride layer; and the first metal fill material comprises copper at an atomic percentage greater than 95%.

In one embodiment, the downward-protruding divot-fill dielectric portion 122DF is a portion of a dielectric diffusion barrier layer 122 overlying the first conductive interconnect structure 108 and the first dielectric material layer 110, and underlying the second dielectric material layer 126.

In one embodiment, the dielectric diffusion barrier layer 122 comprises a silicon nitride, silicon carbide nitride, silicon carbonitride or silicon oxynitride including nitrogen atoms at a higher atomic percentage than oxygen atoms.

In one embodiment, the dielectric diffusion barrier layer 122 comprises silicon nitride layer; and the device structure further comprises a silicon carbonitride etch stop dielectric layer 124 contacting a top surface of the dielectric diffusion barrier layer 122 and contacting a bottom surface of the second dielectric material layer 126.

In one embodiment, the device structure comprises: a three-dimensional memory device 900 underlying the first dielectric material layer 110 and comprising an alternating stack (32, 46) of insulating layers 32 and electrically conductive layers 46, a two-dimensional array of memory openings 49 vertically extending through the alternating stack (32, 46), and a two-dimensional array of memory opening fill structures 58 located in the two-dimensional array of memory openings 49 and comprising a respective vertical stack of memory elements and a respective vertical semiconductor channel 60; and a two-dimensional array of contact via structures 88 overlying the three-dimensional memory array and electrically connected to a respective one of the vertical semiconductor channels 60, wherein the first conductive interconnect structure 108 is a bit line 10B that is electrically connected to a respective subset of the contact via structures 88 within the two-dimensional array of contact via structures 88.

Although the foregoing refers to particular preferred embodiments, it will be understood that the disclosure is not so limited. It will occur to those of ordinary skill in the art that various modifications may be made to the disclosed embodiments and that such modifications are intended to be within the scope of the disclosure. Compatibility is presumed among all embodiments that are not alternatives of one another. The word “comprise” or “include” contemplates all embodiments in which the word “consist essentially of” or the word “consists of” replaces the word “comprise” or “include,” unless explicitly stated otherwise. Where an embodiment employing a particular structure and/or configuration is illustrated in the present disclosure, it is understood that the present disclosure may be practiced with any other compatible structures and/or configurations that are functionally equivalent provided that such substitutions are not explicitly forbidden or otherwise known to be impossible to one of ordinary skill in the art. All of the publications, patent applications and patents cited herein are incorporated herein by reference in their entirety.

What is claimed is:

1. A device structure, comprising:
a first dielectric material layer;
a first conductive interconnect structure embedded in the first dielectric material layer and comprising a first metallic barrier liner and a first metal fill material portion having a top surface within a first horizontal plane, wherein the first metallic barrier liner laterally surrounds the first metal fill material portion and has a top surface below the first horizontal plane such that a moat-shaped divot is located between the first metal fill material portion and the first dielectric material layer;
a divot-fill dielectric portion located in the moat-shaped divot and contacting the top surface of the first metallic barrier liner;
a second dielectric material layer overlying the first dielectric material layer; and
a second conductive interconnect structure embedded in the second dielectric material layer and contacting at least a segment of the top surface of the first metal fill material portion.

2. The device structure of claim 1, wherein a bottom surface of the second conductive interconnect structure is in direct contact with at least the segment of the top surface of the first metal fill material portion and is in direct contact with at least a segment of a top surface of the divot-fill dielectric portion.

3. The device structure of claim 2, wherein the top surface the divot-fill dielectric portion and the top surface of the first dielectric material layer are located in the first horizontal plane.

4. The device structure of claim 1, wherein a bottom surface of the second conductive interconnect structure is in contact with a segment of the top surface of the first dielectric material layer.

5. The device structure of claim 1, wherein a periphery of a bottom surface of the second conductive interconnect structure is in contact with at least a segment of the top surface of the first metal fill material portion, at least a segment of a top surface of the divot-fill dielectric portion, and a segment of the top surface of the first dielectric material layer.

6. The device structure of claim 1, wherein the divot-fill dielectric portion has an annular configuration and laterally surrounds an upper portion of the first metal fill material portion.

7. The device structure of claim 1, wherein each sidewall of the first metal fill material portion comprises:
a respective lower sidewall segment in contact within a respective inner sidewall of the first metallic barrier liner; and
a respective upper sidewall segment in contact with a respective inner sidewall of the divot-fill dielectric portion.

8. The device structure of claim 1, wherein:
vertically-extending portions of the first metallic barrier liner have a first thickness; and
the divot-fill dielectric portion has the first thickness.

9. The device structure of claim 1, wherein the second conductive interconnect structure comprises:
a second metallic barrier liner having a bottom surface within the first horizontal plane, having a top surface located within a second horizontal plane, and contacting at least a segment of the top surface of the first metal fill material portion; and
a second metal fill material portion that is laterally surrounded by the second metallic barrier liner and having a top surface within the second horizontal plane.

10. The device structure of claim 9, wherein:
the second metallic barrier liner comprises a titanium layer, a tantalum layer, a titanium nitride layer, a tantalum nitride layer, a tungsten nitride layer, or a molybdenum nitride layer; and
the second metal fill material portion comprises tungsten, cobalt, ruthenium, titanium, tantalum, or molybdenum.

11. The device structure of claim 1, wherein:
the first conductive interconnect structure comprises a bit line of a semiconductor device;
the second conductive interconnect structure comprises a metal via structure;
the first metallic barrier liner comprises a titanium layer, a tantalum layer, a titanium nitride layer or a tantalum nitride layer; and
the first metal fill material comprises copper at an atomic percentage greater than 95%.

12. The device structure of claim 1, wherein the divot-fill dielectric portion comprises a downward-protruding divot-fill dielectric portion of a dielectric diffusion barrier layer overlying the first conductive interconnect structure and the first dielectric material layer, and underlying the second dielectric material layer.

13. The device structure of claim 12, wherein the dielectric diffusion barrier layer comprises a silicon nitride layer, an aluminum nitride layer, a silicon carbonitride layer or a silicon oxynitride layer including nitrogen atoms at a higher atomic percentage than oxygen atoms.

14. The device structure of claim 12, wherein:
the dielectric diffusion barrier layer comprises a silicon nitride layer; and
the device structure further comprises a silicon carbonitride etch stop dielectric layer contacting a top surface of the dielectric diffusion barrier layer and contacting a bottom surface of the second dielectric material layer.

15. The device structure of claim 1, further comprising:
a three-dimensional memory device underlying the first dielectric material layer and comprising an alternating stack of insulating layers and electrically conductive layers, a two-dimensional array of memory openings vertically extending through the alternating stack, and a two-dimensional array of memory opening fill structures located in the two-dimensional array of memory openings and comprising a respective vertical stack of memory elements and a respective vertical semiconductor channel; and
a two-dimensional array of contact via structures overlying the three-dimensional memory array and electrically connected to a respective one of the vertical semiconductor channels,
wherein the first conductive interconnect structure is a bit line that is electrically connected to a respective subset of the contact via structures within the two-dimensional array of contact via structures.

16. A method of forming a device structure, comprising:
forming a first dielectric material layer over a substrate;
forming a first conductive interconnect structure in the first dielectric material layer, wherein the first conductive interconnect structure comprises a first metallic barrier liner and a first metal fill material portion having a top surface within a first horizontal plane including a top surface of the first dielectric material layer and laterally surrounded by the first metallic barrier liner;
selectively recessing a top surface of the first metallic barrier liner relative to the first metal fill material portion and the first dielectric material layer, wherein a moat-shaped divot is formed between the first metal fill material portion and the first dielectric material layer;
forming a dielectric diffusion barrier layer over the first conductive interconnect structure and the first dielectric material layer, wherein the dielectric diffusion barrier layer comprises a downward-protruding divot-fill dielectric portion filling the moat-shaped divot;
forming a second dielectric material layer over the dielectric diffusion barrier layer; and
forming a second conductive interconnect structure through the dielectric diffusion barrier layer and the second dielectric material layer and directly on at least a segment of the top surface of the first metal fill material portion.

17. The method of claim 16, wherein the selectively recessing of the top surface of the first metallic barrier liner comprises selectively wet etching the first metallic barrier liner selective to the first metal fill material portion and the first dielectric material layer.

18. The method of claim 16, wherein the moat-shaped divot has a uniform width throughout.

19. The method of claim 16, further comprising forming a vertically-extending cavity through the second dielectric material layer and the dielectric diffusion barrier layer, wherein:
at least the segment of the top surface of the first metal fill material portion is exposed underneath the vertically-extending cavity;
at least a segment of the downward-protruding divot-fill dielectric portion is exposed underneath the vertically-extending cavity; and
the second conductive interconnect structure is formed in the vertically-extending cavity.

20. The method of claim 19, wherein:
a segment of the top surface of the first dielectric material layer is exposed underneath the vertically-extending cavity; and
the second conductive interconnect structure is formed directly on the segment of the top surface of the first dielectric material layer.
